(19) United States
(12) Patent Application Publication
(10) Pub. No.: US 2025/0309045 A1
(43) Pub. Date: Oct. 2, 2025

(54) LIQUID COOLING TO CPU/MCM BOND AND PACKAGE PROCESS FLOW

(71) Applicant: Adeia Semiconductor Bonding Technologies Inc., San Jose, CA (US)

(72) Inventors: Gaius Gillman Fountain, JR., Youngsville, NC (US); Belgacem Haba, Saratoga, CA (US); Rajesh Katkar, Milpitas, CA (US); Ron Zhang, Sunnyvale, CA (US); Laura Mirkarimi, Sunol, CA (US)

(21) Appl. No.: 18/812,675

(22) Filed: Aug. 22, 2024

Related U.S. Application Data
(60) Provisional application No. 63/571,974, filed on Mar. 29, 2024.
(60) Provisional application No. 63/651,771, filed on May 24, 2024.

(51) Int. Cl. H01L 23/46; H01L 21/48; H01L 23/00; H01L 23/31; H01L 25/00; H01L 25/065

(52) U.S. Cl. CPC H01L 23/46; H01L 21/4882; H01L 23/3107; H01L 24/08; H01L 25/0652; H01L 25/50; H01L 2224/08245; H01L 2225/06565

(57) ABSTRACT

In some implementations, a method of manufacturing a cooling apparatus includes forming an integrated cooling assembly by attaching a cold plate to a backside of a first die. A first side of the cold plate is spaced apart from the first die to define a channel volume having an inlet portion and an outlet portion that are closed at a second side of the cold plate opposite to the first side. The method further includes attaching the integrated cooling assembly to an interposer, wherein a plurality of second dies is disposed on the interposer, and subsequent to attaching the integrated cooling assembly to the interposer, opening the inlet portion and the outlet portion of the channel volume.

### CROSS-REFERENCE TO RELATED APPLICATION

This application claims the benefit of U.S. Provisional Patent Application No. 63/571,974, filed Mar. 29, 2024, and U.S. Provisional Patent Application No. 63/651,771, filed May 24, 2024, each of which is incorporated by reference herein in its respective entirety.

### TECHNICAL FIELD

The present disclosure relates to advanced packaging for microelectronic devices, and in particular, cooling systems for device packages and methods of manufacturing the same.

### BACKGROUND

Energy consumption poses a critical challenge for the future of large-scale computing as the world's computing energy requirements are rising at a rate that most would consider unsustainable. Some models predict that the information, communication, and technology (ICT) ecosystem could exceed 20% of global electricity use by 2030, with direct electrical consumption by large-scale computing centers accounting for more than one-third of that energy usage. A significant portion of the energy used by such large-scale computing centers is devoted to cooling, since even small increases in operating temperatures can negatively impact the performance of microprocessors, memory devices, and other electronic components. While some of this energy is expended to operate the cooling systems that are directly cooling the chips (e.g., heat spreaders, heat pipes, etc.), energy consumption/costs for indirect cooling can also be quite staggering. Indirect cooling energy costs include, for example, cooling or air conditioning of data center buildings. Data center buildings can house thousands, to tens of thousands or more, of high-performance chips in server racks, and each of those high-performance chips is a heat source. An uncontrolled ambient temperature in a data center will adversely affect the performance of the individual chips, and the data center system performance as a whole.

Thermal dissipation in high-power density chips (semiconductor devices/die) is also a critical challenge as improvements in chip performance, e.g., through increased gate or transistor density due to advanced processing nodes, evolution of multi-core microprocessors, etc., have resulted in increased power density and a corresponding increase in thermal flux that contributes to elevated chip temperatures. Higher density of transistors also increases the length of metal wiring on the chips, which generates its own additional thermal flux due to Joule heating of these wires due to higher currents. These elevated temperatures are undesirable as they can degrade the chip's operating performance, efficiency, reliability, and amount of remaining life. Cooling systems used to maintain the chip at a desired operating temperature typically remove heat using one or more heat dissipation devices, e.g., thermal spreaders, heat pipes, cold plates, liquid cooled heat pipe systems, thermal-electric coolers, heat sinks, etc. One or more thermal interface material(s), such as, for example, thermal paste, thermal adhesive, or thermal gap filler, may be used to facilitate heat transfer between the surfaces of a chip and heat dissipation device(s). A thermal interface material(s) (TIM(s)) is any material that is inserted between two components to enhance the thermal coupling therebetween. Unfortunately, the combined thermal resistance of (i) the thermal resistance of interfacial boundary regions between a TIM(s) and the chip and/or the heat dissipation device(s), and (ii) the thermal resistance of a thermal interface material(s) itself can inhibit heat transfer from the chip to the heat dissipation devices, undesirably reducing the cooling efficiency of the cooling system.

Generally speaking, there are multiple components between the heat dissipating sources (i.e., active circuitry) in the chips and the heat dissipation devices, each of which contributes to the system thermal resistance cumulatively along the heat transfer paths and raises chip junction temperatures from the ambient.

Such cooling systems can suffer from reduced cooling efficiency due to the design and manufacture of system components. In some other approaches, manufacturing a cooling system introduces debris and/or other contaminants at thermal interfaces between the chip and the heat dissipation device(s). The debris and/or other contaminants undesirably damages parts of the cooling system at the thermal interfaces. Furthermore, the debris and/or other contaminants undesirably interferes with the heat transfer path, increases thermal resistance, and reduces the cooling efficiency of the cooling system. These other approaches can be complicated and not adaptable for batch processes, undesirably increasing manufacturing cost and time.

Accordingly, there exists a need in the art for improved energy-efficient cooling systems, by reducing system thermal resistance, and methods of manufacturing the same.

### SUMMARY

Embodiments herein provide methods of manufacturing one or more cooling apparatuses including an integrated cooling assembly, the integrated cooling assembly including a cold plate attached (e.g., directly bonded) to a first die, and one or more second dies communicatively coupled to the first die. The methods described herein prevent exposure of coolant channels of the cold plate during manufacture of the cooling apparatuses, desirably mitigating debris and/or contaminants from entering the coolant channels and protecting the cooling apparatus.

Advantageously, the methods of manufacturing one or more cooling apparatuses described herein mitigate debris and/or contaminants that can undesirably damage parts of the cooling assembly, interfere with a heat transfer path between a coolant and one or more devices, increase thermal resistance, and reduce the cooling efficiency of the cooling system. Beneficially, the methods described herein are adaptable to batch processes. That is, the methods include one or more steps that can be performed consecutively for manufacturing a cooling apparatus or parts thereof. Beneficially, mitigating the debris and/or contaminants protects the integrated cooling assembly or parts thereof, such as channel sidewalls of the cold plate that define coolant channels in the channel volume when the cold plate is bonded to a die. Beneficially, the methods described herein desirably prevent the debris and/or contaminants from contaminating a coolant fluid when operating the cooling apparatus.

One general aspect includes a method for manufacturing a cooling apparatus. The method includes forming an integrated cooling assembly including a cold plate and a first die. The cold plate has first and second portions. The integrated cooling assembly is formed by directly bonding the first portion of the cold plate to a backside of the first die. The second portion of the cold plate is spaced apart from the backside of the first die to define a channel volume having an inlet portion and an outlet portion that are closed at a cold plate backside of the cold plate facing away from the backside of the first die. The method further includes attaching the integrated cooling assembly to an interposer, wherein a plurality of second dies is disposed on the interposer, and, subsequent to attaching the integrated cooling assembly to the interposer, opening the inlet portion and the outlet portion of the channel volume.

Implementations of the method for manufacturing the cooling apparatus may include one or more of the following features. The method may further include directly bonding the plurality of second dies to the interposer, wherein the plurality of second dies is disposed adjacent to the first die. The method may further include flip chip bonding the interposer to a package substrate. The second portion of the cold plate may be patterned. The inlet portion and the outlet portion may be closed by respective portions of the cold plate. In embodiments where the inlet portion and the outlet portion are closed by respective portions of the cold plate, opening the inlet portion and the outlet portion may include thinning the cold plate backside to remove the respective portions of the cold plate. In embodiments where the inlet portion and the outlet portion are closed by respective portions of the cold plate, opening the inlet portion and the outlet portion may include patterning the cold plate backside to remove the respective portions of the cold plate. Patterning the cold plate may include forming a resist pattern over the cold plate backside, the resist pattern having a pattern corresponding to the inlet portion and the outlet portion and etching the respective portions of the cold plate through the pattern. The inlet portion and the outlet portion may be closed by respective removable plugs. Opening the inlet portion and the outlet portion may include removing the respective removable plugs. The cold plate may include a removable film disposed over at least a portion of the cold plate backside. The inlet portion and the outlet portion may be closed by the removable film. Opening the inlet portion and the outlet portion may include removing the removable film. Prior to opening the inlet portion and the outlet portion, the method may further include forming an encapsulant layer over the cold plate and thinning the encapsulant layer to reveal the cold plate backside. The method may further include singulating the interposer and the encapsulant layer. A thickness of the integrated cooling assembly in a direction orthogonal to the backside of the first die may be different than a thickness of each of the plurality of second dies in the same direction. The method may further include attaching one or more heat dissipation devices to the plurality of second dies. Attaching the integrated cooling assembly to the interposer may form interconnections between the first die and each of the plurality of second dies. The cold plate may be attached to the backside of the first die using direct dielectric bonds. The cold plate may be attached to the backside of the first die using direct hybrid bonds. The cold plate may include a perimeter sidewall as the first portion of the cold plate, a top portion as the second portion of the cold plate, and a cavity divider comprising cavity sidewalls. The perimeter sidewall may extend downwardly from the top portion to the backside of the first die to define a perimeter of the cold plate. The cavity divider may extend downwardly from the top portion towards the backside of the first die. The cavity sidewalls, the perimeter sidewall, and the backside of the first die may collectively define the channel volume therebetween.

One general aspect includes a cooling apparatus including an interposer, an integrated cooling assembly, the integrated cooling assembly including a cold plate and a first die. The cold plate includes a first portion that is directly bonded to a backside of the first die. The integrated cooling assembly is attached to the interposer, and a second die is communicatively coupled to the first die through the interposer, wherein a thickness of the integrated cooling assembly in a direction orthogonal to the backside of the first die is less than a thickness of the second die in the same direction.

Implementations of the cooling apparatus may include one or more of the following features. The cooling apparatus may include a die stack having an overall thickness in the same direction. The thickness of the integrated cooling assembly may be less than the overall thickness of the die stack. The thickness of the integrated cooling assembly may be different than a thickness of each die of the die stack in the same direction. The cooling apparatus may include a third die communicatively coupled to the first die through the interposer. A thickness of the third die in the direction orthogonal to the backside of the first die may be greater than the thickness of the integrated cooling assembly in the same direction. In some embodiments, the thickness of the third die is about the same as the thickness of the second die in the same direction. In some other embodiments, the thickness of the third die is different than the thickness of the second die in the same direction. The cooling apparatus may include an encapsulant layer disposed over the interposer, wherein the interposer and the encapsulant layer are singulated. The encapsulant layer may be planarized such that a thickness of the encapsulant layer in the direction orthogonal to the backside of the first die is about the same as the thickness of the second die in the same direction. The second die may be one of a plurality of dies disposed on the interposer and adjacent to the first die, the plurality of dies being communicatively coupled to the first die through the interposer. The cold plate may include a second portion and a cold plate backside facing away from the backside of the first die, the second portion being spaced apart from the backside of the first die to define a channel volume having an inlet portion and an outlet portion that are open at the cold plate backside. The cooling apparatus may further include a structural material layer bonded to the cold plate backside, the structural material layer having a pattern corresponding to the inlet portion and the outlet portion. A total thickness of the structural material layer and the integrated cooling assembly in the direction orthogonal to the backside of the first die may be about the same as the thickness of the second die in the same direction. The first portion of the cold plate may be directly bonded to the backside of the first die by direct dielectric bonds. The first portion of the cold plate may be directly bonded to the backside of the first die by direct hybrid bonds. A device package may include the cooling apparatus. The device package may further include a package substrate, wherein the integrated cooling assembly is attached to the package substrate. The device package may further include a package cover disposed over the integrated cooling assembly. The package cover may include an inlet opening and an outlet opening disposed therethrough. A channel volume of the cold plate may be in fluid communication with the inlet opening and the outlet opening of the package cover. The cooling apparatus may include a perimeter sidewall as the first portion of the cold plate, a top portion, and a cavity divider comprising cavity sidewalls. The perimeter sidewall may extend downwardly from the top portion to the backside of the first die to define a perimeter of the cold plate. The cavity divider may extend downwardly from the top portion towards the backside of the first die. The cavity sidewalls, the perimeter sidewall, and the backside of the first die may collectively define a channel volume therebetween.

One general aspect includes a method for manufacturing a cooling apparatus. The method includes forming an integrated cooling assembly by directly bonding a first portion of a cold plate to a backside of a first die. A second portion of the cold plate is spaced apart from the backside of the first die to define a channel volume having an inlet portion and an outlet portion that are open at a cold plate backside of the cold plate. The method further includes closing the inlet portion and the outlet portion by attaching a side of a substrate to the cold plate backside. The substrate comprises respective planarized material portions disposed at the side of the substrate and over each of the inlet portion and the outlet portion. The method further includes attaching the integrated cooling assembly to an interposer and, subsequent to attaching the integrated cooling assembly to the interposer, opening the inlet portion and the outlet portion by removing the respective planarized material portions.

Implementations of the cooling apparatus may include one or more of the following features. The method may further include preparing the substrate having cavities disposed at the first side of the substrate, wherein a first cavity of the cavities corresponds to the inlet portion and a second cavity of the cavities corresponds to the outlet portion, forming a planarizable material in the cavities, and forming the respective planarized material portions by planarizing the side of the substrate and the planarizable material. The side of the substrate may be a first side of the substrate. Removing the respective planarized material portions may include revealing the respective planarized material portions by thinning a second side of the substrate opposite to the first side of the substrate and etching the respective planarized material portions through the second side of the substrate to the first side of the substrate. The respective planarized material portions may include an inorganic dielectric material. The inorganic dielectric material may include an oxide. The cold plate may include a perimeter sidewall as the first portion of the cold plate, a top portion as the second portion of the cold plate, and a cavity divider comprising cavity sidewalls. The perimeter sidewall may extend downwardly from the top portion to the backside of the first die to define a perimeter of the cold plate. The cavity divider may extend downwardly from the top portion towards the backside of the first die. The cavity sidewalls, the perimeter sidewall, and the backside of the first die may collectively define the channel volume therebetween.

### BRIEF DESCRIPTION OF THE DRAWINGS

The above and other objects and advantages of the disclosure will be apparent upon consideration of the following detailed description, taken in conjunction with the accompanying drawings, in which:

FIG. 1 illustrates a device package with an external heat sink;

FIG. 2A is a schematic plan view of an example of a system panel, in accordance with embodiments of the present disclosure;

FIG. 2B is a schematic partial sectional side view of a device package mounted on a PCB, in accordance with embodiments of the present disclosure;

FIG. 2C is a schematic exploded isometric view of the device package in FIG. 2B.

FIG. 3 is a schematic sectional view of an example device package, in accordance with embodiments of the present disclosure, that may be used with the system panel;

FIG. 4 is a schematic sectional view of an integrated cooling assembly of the device package, in accordance with embodiments of the present disclosure;

FIG. 5 is a schematic sectional view of another example device package, in accordance with embodiments of the present disclosure, that may be used with the system panel;

FIG. 6 shows a method that can be used to manufacture the device package described herein;

FIG. 7 shows a schematic sectional view of a device package including a cooling apparatus attached to a package substrate, in accordance with embodiments of the present disclosure;

FIG. 8 is a flowchart illustrating an example process for manufacturing a cooling apparatus including opening inlet and outlet portions of an integrated cooling assembly that are closed, in accordance with embodiments of the present disclosure;

FIGS. 9-11 show schematic sectional views of example structures during manufacture of a cooling apparatus including opening inlet and outlet portions of an integrated cooling assembly, in accordance with embodiments of the present disclosure;

FIG. 12 is a flowchart illustrating an example process for manufacturing a cooling apparatus including closing the inlet and outlet portions of an integrated cooling assembly, in accordance with embodiments of the present disclosure;

FIG. 13 shows schematic sectional views of example structures during a manufacturing process including closing the inlet and outlet portions of an integrated cooling assembly, in accordance with embodiments of the present disclosure;

FIG. 14 is a flowchart illustrating an example process for manufacturing a cooling apparatus including bonding a substrate that closes the inlet and outlet portions of an integrated cooling assembly, in accordance with embodiments of the present disclosure; and

FIG. 15 shows schematic sectional views of example structures during a manufacturing process including bonding a substrate that closes the inlet and outlet portions of an integrated cooling assembly, in accordance with embodiments of the present disclosure.

The FIGURES herein depict various embodiments of the present disclosure for purposes of illustration only. It will be appreciated that additional or alternative structures, assemblies, systems, and methods may be implemented within the principles set out by the present disclosure.

### DETAILED DESCRIPTION

As used herein, the term “substrate” means and includes any workpiece, wafer, or article that provides a base material or supporting surface from which or upon which components, elements, devices, assemblies, modules, systems, or features of the heat-generating devices, packaging components, and cooling assembly components described herein may be formed or mounted. The term “substrate” also includes semiconductor substrates that provide a supporting material upon which elements of a semiconductor device are fabricated or attached, and any material layers, features, and/or electronic devices formed thereon, therein, or therethrough. Examples of substrate material that may be used in applications that generate high thermal density include, but are not limited to, Si, GaN, SiC, InP, GaP, InGaN, AlGaInP, AlGaAs, etc.

As described below, the semiconductor substrates herein generally have a “device side,” e.g., the side on which semiconductor device elements are fabricated, such as transistors, resistors, and capacitors, and a “backside” that is opposite the device side. The term “active side” should be understood to include a surface of the device side of the substrate and may include the device side surface of the semiconductor substrate and/or a surface of any material layer, device element, or feature formed thereon or extending outwardly therefrom, and/or any openings formed therein. Thus, it should be understood that the material(s) that forms the active side may change depending on the stage of device fabrication and assembly. Similarly, the term “non-active side” (opposite the active side) includes the non-active side of the substrate at any stage of device fabrication, including the surfaces of any material layer, any feature formed thereon, or extending outwardly therefrom, and/or any openings formed therein. Thus, the terms “active side” or “non-active side” may include the respective surfaces of the semiconductor substrate at the beginning of device fabrication and any surfaces formed during material removal, e.g., after substrate thinning operations. Depending on the stage of device fabrication or assembly, the terms “active sides” and “non-active sides” are also used to describe surfaces of material layers or features formed on, in, or through the semiconductor substrate, whether or not the material layers or features are ultimately present in the fabricated or assembled device. For example, in some instances, the term “active side” is used to indicate a surface of a substrate that will in the future, but does not yet, include semiconductor device elements.

Spatially relative terms are used herein to describe the relationships between elements, such as the relationships between substrates, heat-generating devices, cooling assembly components, device packaging components, and other features described below. Unless the relationship is otherwise defined, terms such as “above,” “over,” “upper,” “upwardly,” “outwardly,” “on,” “below,” “under,” “beneath,” “lower,” “top,” “bottom” and the like are generally made with reference to the X, Y, and Z directions set forth by X, Y and Z axes in the drawings. Thus, it should be understood that the spatially relative terms used herein are intended to encompass different orientations of the substrate and, unless otherwise noted, are not limited by the direction of gravity. Unless the relationship is otherwise defined, terms describing the relationships between elements such as “disposed on,” “embedded in,” “coupled to,” “connected by,” “attached to,” “bonded to,” and the like, either alone or in combination with a spatially relevant term, include both relationships with intervening elements and direct relationships where there are no intervening elements. Furthermore, the term “horizontal” is generally made with reference to the X-axis direction and the Y-axis direction set forth in the drawings. The term “vertical” is generally made with reference to the Z-axis direction set forth in the drawings.

Various embodiments disclosed herein include bonded structures in which two or more elements are directly bonded to one another without an intervening adhesive (referred to herein as “direct bonding,” “direct dielectric bonding,” or “directly bonded”). The resultant bonds formed by this technique may be described as “direct bonds” and/or “direct dielectric bonds.” In some embodiments, direct bonding includes the bonding of a single material on the first of the two or more elements and a single material on a second one of the two or more elements, where the single material on the different elements may or may not be the same. For example, bonding a layer of one inorganic dielectric (e.g., silicon oxide) to another layer of the same or different inorganic dielectric. As discussed in more detail below, the process of direct bonding (e.g., direct dielectric bonding) provides a reduction of thermal resistance between a semiconductor device and a cold plate. Examples of dielectric materials used in direct bonding include oxides, nitrides, oxynitrides, carbonitrides, and oxycarbonitrides, etc., such as, for example, silicon oxide, silicon nitride, silicon oxynitride, silicon carbonitride, silicon oxycarbonitride, etc. Direct bonding can also include bonding of multiple materials on one element to multiple materials on the other element (e.g., hybrid bonding). As used herein, the term “hybrid bonding” refers to a species of direct bonding having both i) at least one (first) nonconductive feature directly bonded to another (second) nonconductive feature, and ii) at least one (first) conductive feature directly bonded to another (second) conductive feature, without any intervening adhesive. The resultant bonds formed by this technique may be described as “hybrid bonds” and/or “direct hybrid bonds.” In some hybrid bonding embodiments, there are many first conductive features, each directly bonded to a second conductive feature, without any intervening adhesive. In some embodiments, nonconductive features on the first element are directly bond to nonconductive features of the second element at room temperature without any intervening adhesive, which is followed by bonding of conductive features of the first element directly bonded to conductive features of the second element via annealing at slightly higher temperatures (e.g., >100° C., >200° C., >250° C., >300° C., etc.).

Unless otherwise noted, the terms “cooling assembly” and “integrated cooling assembly” generally refer to a semiconductor device and a cold plate attached to the semiconductor device. Typically, the cold plate is formed with recessed surfaces that define one or more fluid cavities (e.g., coolant chamber volume(s) or coolant channel(s)) between the cold plate and the semiconductor device. In embodiments where the cold plate is formed with plural fluid cavities, each fluid cavity may be defined by cavity dividers and/or sidewalls of the cold plate. For example, cavity dividers may be spaced apart from each other and extend laterally between opposing cold plate sidewalls (e.g., in one direction between a first pair of opposing cold plate sidewalls, or in two directions between orthogonal pairs of opposing cold plate sidewalls). The cavity dividers and the cold plate sidewalls may collectively define adjacent fluid cavities therebetween. The cold plate may comprise a polymer material.

The cold plate may be attached to the semiconductor device by use of a compliant adhesive layer or by direct bonding or hybrid bonding. Direct bonding may include direct dielectric bonding techniques as described herein and may give rise to direct dielectric bonds. Hybrid bonding may include hybrid bonding techniques as described herein and may give rise to direct hybrid bonds. For example, the cold plate may include material layers and/or metal features that facilitate direct bonding or hybrid bonding with the semiconductor device. Beneficially, the backside of the semiconductor device is directly exposed to coolant fluids flowing through the integrated cooling assembly, thus providing for direct heat transfer therebetween. Unless otherwise noted, the integrated cooling assemblies described herein may be used with any desired fluid, e.g., liquid, gas, and/or vapor-phase coolants, such as water, glycol, etc.

Exemplary cooling fluids available for use in the various embodiments include: water (either purified or deionized), a glycol (e.g., ethylene glycol, propylene glycol), glycols mixed with water (e.g., ethylene glycol mixed with water (EGW) or propylene glycol mixed with water (PGW)), dielectric fluids (e.g. fluorocarbons, polyalphaolefin (PAO), isoparaffins, synthetic esters, or very high viscosity index (VHVI) oils), or mineral oils. Depending upon design and operating conditions, these fluids may be used in single-phase liquid, single-phase vapor, two-phase liquid/vapor or two-phase solid/liquid. Additionally, multiple combinations of the aforementioned cooling fluid phases may be employed in various hybrid configurations to meet the particular cooling needs of a respective implementation and still be within the scope of the contemplated embodiments.

Additionally, in some embodiments part or all the cooling is provided by gases. Exemplary gases include atmospheric air and/or one or more inert gases such as nitrogen. Atmospheric air may be taken to mean the mixture of different gases in Earth's atmosphere made up of about 78% nitrogen and 21% oxygen.

Depending on the design needs of a fluid cooling system using the disclosed embodiments, engineered dielectric cooling fluids may be used. Some examples of dielectric fluids used for cooling semiconductors include: 3M™ Fluorinert™ Liquid FC-40—A non-flammable, dielectric fluid that can be used in direct contact with live electronics; 3M™ Novec™ Engineered Fluids-A non-flammable, dielectric fluid that can be used in direct contact with live electronics; Galden® PFPE (perfluoropolyether) products used as heat transfer fluids; EnSolv Fluoro HTF-A solvent with a high boiling point and low pour point that can be used for semiconductor wafer cooling. It is understood that in the selection of the cooling fluid, system design aspects such as operating temperatures and pressures, fluid flow rates, fluid viscosity, and other properties will require evaluation when selecting the appropriate cooling fluid.

In some embodiments, the cooling fluids may contain microparticles and/or nanoparticle additives to enhance the conductivity of the cooling fluid within the integrated cooling assemblies. Choi and Eastman (1995) from Argonne National Laboratory, U.S.A. (Yu et al., 2007) coined the word “nanofluid”. The nanofluid is an engineered fluid prepared by suspending the nano-sized (1-100 nm) particles of metals/non-metals and their oxide(s) with a base/conventional fluid. The suspension of high thermal conductivity metals/non-metals and their oxides nanoparticles enhances the thermal conductivity and heat transfer ability, etc. of the base fluid. The additives to the underlying cooling fluid may comprise for example, nanoparticles of carbon nanotube, nanoparticles of graphene, or nanoparticles of metal oxides. When the cooling fluid contains microparticles, the microparticles are typically 10 microns or in in diameter. Silicon oxide microparticles may be used.

The concentration of these micro or nanoparticles may be less than 1%, less than 0.2%, or less than 0.05%. Depending upon the liquid and micro/nanoparticle type chosen for the nanofluid, higher concentrations of 10% or less, 5% or less, or 2% or less may be used. The cooling fluids may also contain small amounts of glycol or glycols (e.g., propylene glycol, ethylene glycol etc.) to reduce frictional shear stress and drag coefficient in the cooling fluid within the integrated cooling assembly. The availability of different base fluids (e.g., water, ethylene glycol, mineral or other stable oils, etc.) and different nanomaterials provide a variety of nanomaterial options for nanofluid solutions to be used in the various embodiments. These nanomaterial option groups such as aforementioned metals (e.g., Cu, Ag, Fe, Au . . . , etc.), metal oxides (e.g., TiO2, Al2O3, CuO . . . , etc.), carbons (e.g., carbon nanotubes (CNTs), graphene, diamond, graphite . . . , etc.), or a mixture of different types of nanomaterials. Metal nanoparticles (Cu, Ag, Au . . . ), metal oxide nanoparticles (Al2O3, TiO2, CuO), and carbon-based nanoparticles are commonly employed elements. Silicon oxide nanoparticles may also be used. Using nanofluids when practicing the various embodiments disclosed herein can result in increased heat removal efficiencies and effectiveness.

The fluid control design aspects of specific embodiments may require the nanofluids to be magnetic to facilitate either movement or cessation of movement of the fluids within the semiconductor structures. Magnetic nanofluids (MNFs) are suspensions of a non-magnetic base fluid and magnetic nanoparticles. The magnetic nanoparticles may be coated with surfactant layers such as oleic acid to reduce particle agglomeration and/or settling. Magnetic nanoparticles used in MNFs are usually made of metal materials (ferromagnetic materials) such as iron, nickel, cobalt, as well as their oxides such as spinel-type ferrites, magnetite (Fe3O4), and so forth. The magnetic nanoparticles used in MNFs typically range in size from about 1 to 100 nanometers (nm).

This disclosure describes embodiments involving the architecture of system and component elements that can be employed to provide for the cooling of semi-conductor components, packaging, and boards. However, those skilled in the art will appreciate the disclosed components and arrangements can be deployed and used in scenarios where component heat up or thermal warm up is desired for a component that is currently outside the low end of the desired operational range. Components that are outside the low end of their operational range can, if started in a cold environment, experience thermal warping or cracking up to and including thermal overexpansion and contact separation that may impair the successful operation of the system. Therefore, in these scenarios, the architectures and embodiments disclosed herein can be used where the indirect thermal solutions supporting them are repurposed or operated in a hybrid configuration to provide warming fluids or heat transfer media to accomplish the warm-up or heat-up scenario. These scenarios are controlled by systems not shown here to bring temperatures up at a speed or timing that enables the materials to avoid the excessive thermal expansion or unequal thermal expansion that may occur among the materials of the semiconductor or packaging being serviced by the thermal solution. Once the component or packaging is brought up into the normal operating range, it can be safely started and brought to a useful operational state.

Considering the warm-up or heat-up embodiments introduced above, the balance of this disclosure and terms used should be viewed in a light that also considers the design option for such warm-up or heat-up. Thus, where terms such as cooling channel, cooling chamber volume, and cooling port are used, for example, such terms could also be considered as a thermal control channel, a thermal control volume, or a thermal control port, respectively. A person of skill would understand that heat flux or heat transfer would go in a different direction, but the design concepts are similar and can be successfully employed in the various embodiments.

In some embodiments, a cooling channel is a liquid cooling channel, and a liquid may flow through the liquid cooling channel. In some embodiments, the liquid may comprise a water and/or glycol (e.g., propylene glycol, ethylene glycol, and mixtures thereof).

As described below, coolant fluid flowing through a cold plate may be used to control the temperature of semiconductor devices. The fluid flowing across the surface of the semiconductor device absorbs heat and conducts heat away from the semiconductor device.

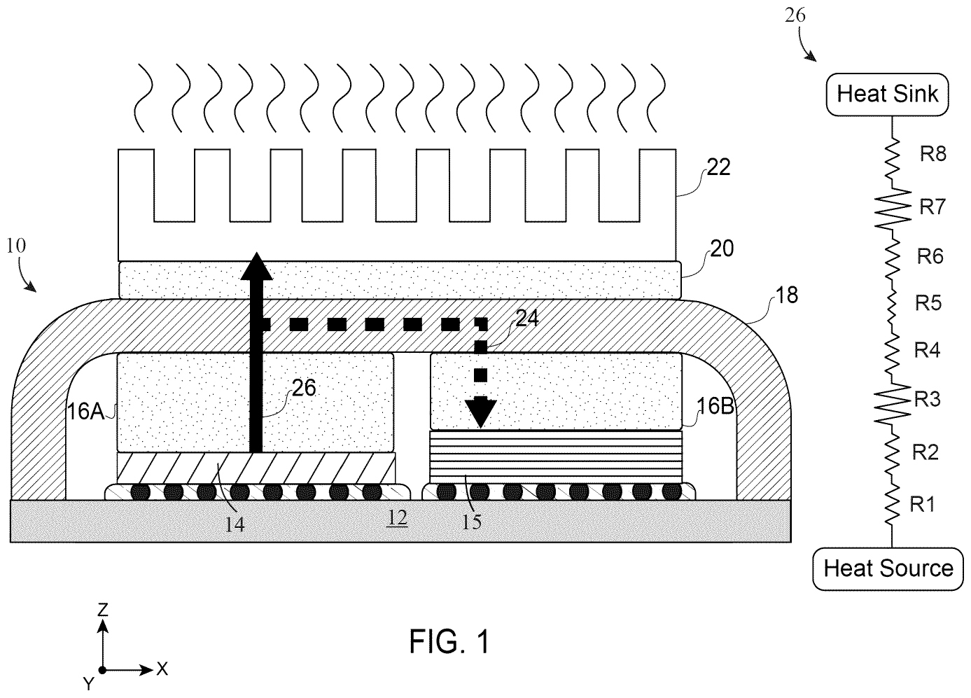

FIG. 1 is a schematic side view of a device package 10 and a heat sink 22 attached to the device package 10. The device package 10 typically includes a package substrate 12, a first device 14, a device stack 15, a heat spreader 18, and first TIM layers 16A, 16B thermally coupling the first device 14 and the device stack 15 to the heat spreader 18. The device package 10 is thermally coupled to the heat sink 22 through a second TIM layer 20. The TIM layers 16A, 16B, 20 facilitate thermal contact between components in the device package 10 and between the device package 10 and the heat sink 22.

As heat flux density increases with increasing power density in advanced semiconductor devices, the cumulative thermal resistance of the system illustrated in FIG. 1 is increasingly problematic as heat cannot be dissipated quickly enough to allow semiconductor devices to run at optimal power. Consequently, the energy efficiency of semiconductor devices is reduced. Furthermore, heat is transferred between semiconductor devices within the device package 10, as shown with heat transfer path 24 (illustrated as a dashed line), where heat may be undesirably transferred from the first device 14 having a high heat flux, such as a central processing unit (CPU) or a graphical processing unit (GPU), to the device stack 15 having low heat flux, such as memory, through the heat spreader 18.

For example, as shown in FIG. 1, each device package component and the respective interfacial boundaries therebetween have a corresponding thermal resistance that forms heat transfer path 26 (illustrated by arrow 26 in FIG. 1). The right-hand side of FIG. 1 illustrates the heat transfer path 26 as a series of thermal resistances R1-R8 between a heat source and a heat sink. Here, R1 is the thermal resistance of the bulk semiconductor material of the first device 14. R3 and R7 are the thermal resistances of the first TIM layers 16A, 16B and the second TIM layer 20, respectively. R5 is the thermal resistance of the heat spreader 18. R2, R4, R6, and R8 represent the thermal resistance at the interfacial region of the components (e.g., contact resistances). In a typical cooling system, R3 and R7 may account for 80% or more of the cumulative thermal resistance of the heat transfer path 26, and R5 may account for 5% or more. R1 of the first device 14 and R2, R4, R6, and R8 of the interfaces account for the remaining cumulative thermal resistance. Accordingly, embodiments described herein provide for integrated cooling assemblies embedded within a device package. The embedded cooling assemblies shorten the thermal resistance path between a semiconductor device and a heat sink and reduce thermal communication between semiconductor devices disposed in the same device package, such as described in relation to the figures below.

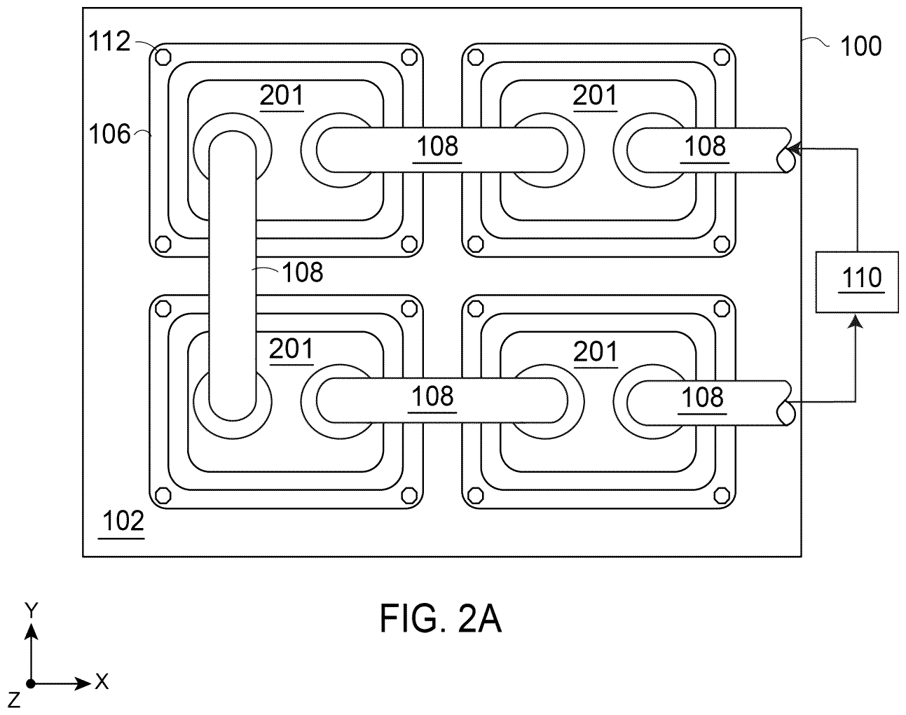

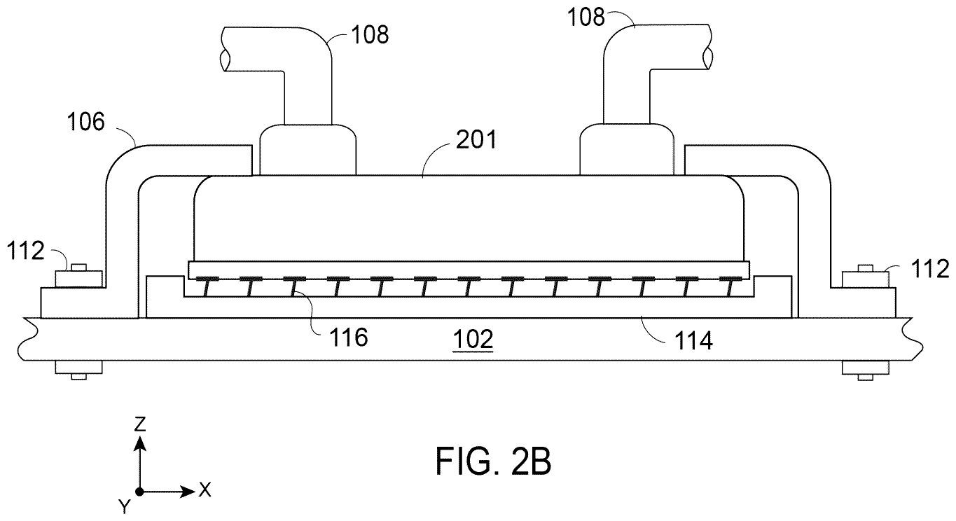

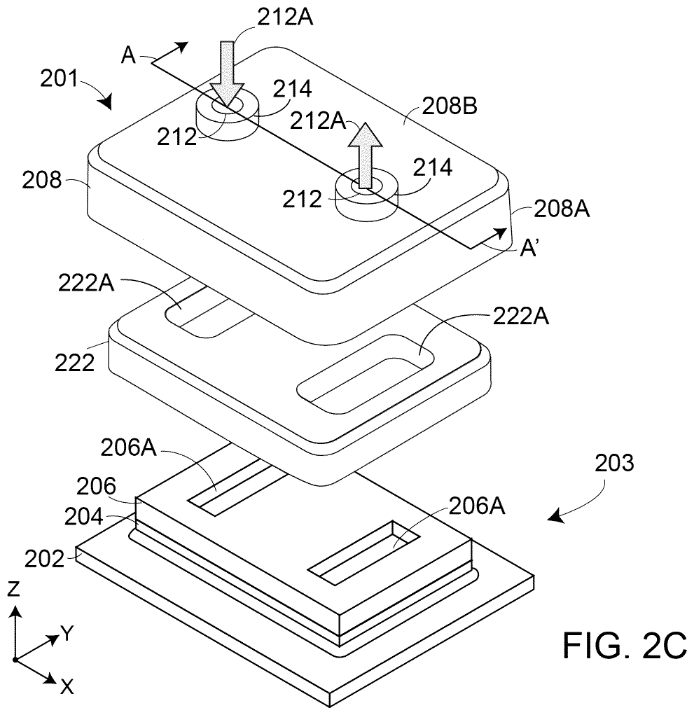

FIG. 2A is a schematic plan view of an example of a system panel 100, in accordance with embodiments of the present disclosure. Generally, the system panel 100 includes a printed circuit board (PCB) 102, a plurality of device packages 201 mounted to the PCB 102, and a plurality of coolant lines 108 fluidly coupling each of the device packages 201 to a coolant source 110. It is contemplated that coolant fluid may be delivered to each of the device packages 201 in any desired fluid phase, e.g., liquid, vapor, gas, or combinations thereof, and may flow out from each device package 201 in the same phase or a different phase. In some embodiments, the coolant fluid is delivered to the device packages 201 and returned therefrom as a liquid, whereby the coolant source 110 may comprise a heat exchanger or chiller to maintain the coolant fluid at a desired temperature. In other embodiments, the coolant fluid may be delivered to the device packages 201 as a liquid, vaporized to a vapor within the device packages 201, and returned to the coolant source 110 as a vapor. In those embodiments, the device packages 201 may be fluidly coupled to the coolant source 110 in parallel, and the coolant source 110 may include or further include a compressor (not shown) for condensing the received vapor to a liquid form.

FIG. 2B is a schematic partial sectional side view of a portion of the system panel 100 of FIG. 2A. As shown, each device package 201 is fluidly coupled to the plurality of coolant lines 108 and is disposed in a socket 114 of the PCB 102 and connected thereto using a plurality of pins 116, or by other suitable connection methods, such as solder bumps (not shown). The device package 201 may be seated in the socket 114 and secured to the PCB 102 using a mounting frame 106 and a plurality of fasteners 112, e.g., compression screws, collectively configured to exert a relatively uniform downward force on the upward facing edges of the device package 201. The uniform downward force ensures proper pin contact between the device package 201 and the socket 114.

FIG. 2C is a schematic exploded isometric view of an example device package 201, in accordance with embodiments of the present disclosure. Generally, the device package 201 includes a package substrate 202, an integrated cooling assembly 203 disposed on the package substrate 202, and a package cover 208 disposed on a peripheral portion of the package substrate 202. Suitable materials that may be used in the package cover 208 include copper, aluminum, metal alloys, etc. The package cover 208 extends over the integrated cooling assembly 203 so that the integrated cooling assembly 203 is disposed between the package substrate 202 and the package cover 208. The integrated cooling assembly 203 typically includes a semiconductor device 204 and a cold plate 206 bonded to the semiconductor device 204. In some embodiments, the cold plate 206 may comprise substrate material like silicon, glass, ceramic, etc. Although the lateral dimensions (or footprint) of the cold plate 206 are shown to be the same or similar to the lateral dimensions (or footprint) of the semiconductor device 204, the footprint of the cold plate 206 may be smaller or larger in one or both directions when compared to the footprint of the semiconductor device 204.

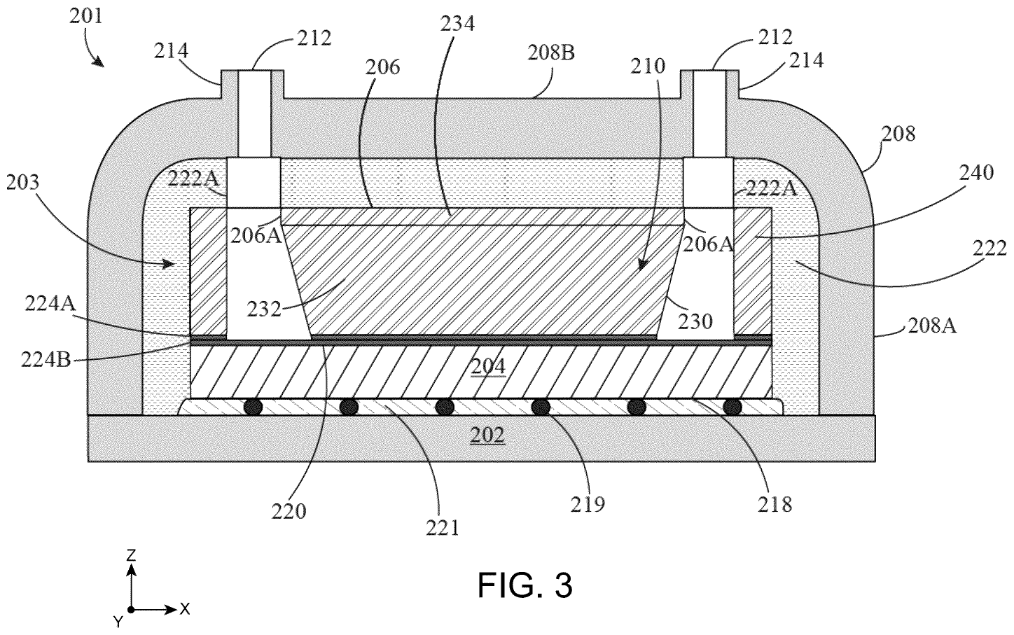

As shown, the device package 201 further includes a sealing material layer 222 that forms a coolant fluid impermeable barrier between the package cover 208 and the integrated cooling assembly 203 that prevents leaking of the coolant fluid outside of the cooling assembly and prevents coolant fluid from reaching an active side 218 (discussed below in relation to FIG. 3) of the semiconductor device 204 and causing damage thereto. In some embodiments, the sealing material layer 222 comprises an adhesive material that reliably attaches the package cover 208 to the integrated cooling assembly 203. In some embodiments, the sealing material layer 222 comprises a polymer or epoxy material that extends upwardly from the package substrate 202 to encapsulate and/or surround at least a portion of the semiconductor device 204. In some embodiments, the sealing material layer 222 may also comprise conductive material, e.g., solder. In other embodiments, the sealing material layer 222 is formed from a molding compound, e.g., a thermoset resin, that when polymerized, forms a hermetic seal between the package cover 208 and the cold plate 206. Here, the coolant fluid is delivered to the cold plate 206 through openings 222A disposed through the sealing material layer 222. As shown, the openings 222A are respectively in registration and fluid communication with inlet and outlet openings 212 of the package cover 208 thereabove and inlet and outlet openings 206A in the cold plate 206 therebelow.

It will be understood that the openings are shown in a section view. The openings may have any cross-sectional shape that allows fluid to flow therethrough (e.g., rectangular, square, hexagonal or circular cross-sections). For example, the inlet and outlet openings 206A of the cold plate 206 may form an elongated shape extending from one side of the cold plate 206 to another side of the cold plate 206. For example, the inlet and outlet openings 206A may form any shape having a length greater than a width in the X-Y plane (e.g., a rectangular or a trapezoidal shape). A shape in the X-Y plane of the openings 222A disposed through the sealing material layer 222 may be substantially the same as the shape of the inlet and outlet openings 206A of the cold plate 206 in the same place. Furthermore, it will be understood that all references to an opening throughout the present disclosure refer to an opening defined by a sidewall (e.g., opening sidewall).

Generally, the package substrate 202 includes a rigid material, such as an epoxy or resin-based laminate, that supports the integrated cooling assembly 203 and the package cover 208. The package substrate 202 may include conductive features disposed in or on the rigid material that electrically couples the integrated cooling assembly 203 to a system panel, such as the PCB 102.

FIG. 3 is a schematic sectional view in the X-Z plane of the device package 201 taken along line A-A′ of FIG. 2C. As illustrated in FIG. 3, the semiconductor device 204 includes the active side 218 that includes device components, e.g., transistors, resistors, and capacitors, formed thereon or therein, and a non-active side, here the semiconductor device backside 220, opposite the active side 218. As shown, the active side 218 is positioned adjacent to and facing towards the package substrate 202. The active side 218 may be electrically connected to the package substrate 202 by use of conductive bumps 219, which are encapsulated by a first underfill layer 221 disposed between the semiconductor device 204 and the package substrate 202. The first underfill layer 221 may comprise a cured polymer resin or epoxy, which provides mechanical support to the conductive bumps 219 and protects against thermal fatigue. In some embodiments, the active side 218 may be electrically connected to another package substrate, another active die, or another passive die (e.g. interposer) using hybrid bonding or conductive bumps 219. The cold plate 206 may be disposed above the package substrate 202 with the semiconductor device 204 disposed therebetween. For example, the semiconductor device 204 (and the first underfill layer 221) may be disposed between the cold plate 206 and the package substrate 202. In some embodiments, the cold plate 206 may be disposed directly on the package substrate 202.

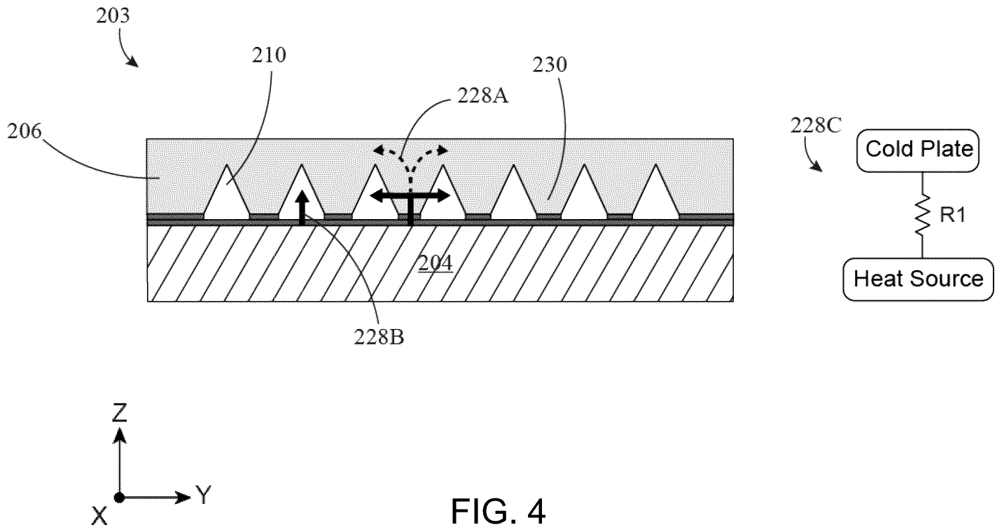

Here, the cold plate 206 comprises a top portion 234 and a sidewall 240 (e.g., a perimeter sidewall defining a perimeter of the cold plate 206) extending downwardly from the top portion 234 to the backside 220 of the semiconductor device 204. The top portion 234, the perimeter sidewall 240, and the backside 220 of the semiconductor device 204 collectively define at least one coolant channel 210 therebetween. The cold plate 206 comprises cavity dividers (e.g., support features 230) extending downwardly from the top portion 234 towards the backside 220 of the semiconductor device 204. The cavity dividers (e.g., support features 230) may extends laterally and in parallel between an inlet opening 206A of the cold plate 206 and an outlet opening 206A of the cold plate 206 to define coolant channels 210 therebetween. It should be appreciated that, the cold plate 206 may comprise one cavity divider (e.g., one of the support features 230) which forms two coolant channels (e.g., one coolant channel on either side of the cavity divider (e.g., the one of the support features 230)) by means of the cavity divider (e.g., the one of the support features 230) and portions of the perimeter sidewall 240. More specifically, coolant channels 210 may be formed between the cavity divider (e.g., the one of the support features 230) and a portion of the perimeter sidewall 240 extending parallel to the cavity divider (e.g., the one of the support features 230). Alternatively, in other embodiments, the cold plate 206 may comprise plural cavity dividers (e.g., the support features 230), for example two cavity dividers, five cavity dividers, or six cavity dividers (as illustrated in FIG. 4). In such examples, the cold plate 206 comprises more than two coolant channels 210, for example three coolant channels, four coolant channels, seven coolant channels, or more, defined between the cavity dividers (e.g., the support features 230) and/or the cavity divider(s) (e.g., support feature(s) 230) and the perimeter sidewall 240.

The cavity dividers (e.g., the support features 230) comprise cavity sidewalls 232 which form surfaces of corresponding coolant channels 210. In embodiments where plural cavity dividers (e.g., the support features 230) extend in parallel to each other, cavity sidewalls 232 of adjacent cavity dividers (e.g., adjacent support features of the support features 230) are opposite (e.g., facing) each other. In embodiments comprising a single cavity divider (e.g., a single support feature of the support features 230), a first cavity sidewall may be opposite (e.g., face) a first portion of the perimeter sidewall 240 extending parallel to and facing the first cavity sidewall. A second cavity sidewall may be opposite (e.g., face) a second portion of the perimeter sidewall 240 extending parallel to and facing the second cavity sidewall. The first portion of the perimeter sidewall 240 may be an opposite side of the cold plate 206 to the second portion of the perimeter sidewall 240. For example, in embodiments where the cold plate 206 is rectangular, first and second opposing sides of the rectangular cold plate 206 form the first and second portions of the perimeter sidewall 240.

The cavity dividers (e.g., the support features 230) may be continuous cavity dividers which extend continuously (e.g., in the Y-axis direction) between the inlet opening 206A and the outlet opening 206A of the cold plate 206.

With reference to FIG. 3, coolant channels 210 may be defined by:
the backside 220 of the semiconductor device 204, which forms lower coolant channel surfaces;
portions of the perimeter sidewall 240 extending in the Y-axis direction, which form end surfaces of the coolant channels 210;
the cavity sidewalls 232, which form inner surfaces of the coolant channels 210 in the X-axis direction; and
portions of the perimeter sidewall 240 extending in the X-axis direction, which form outer surfaces of the coolant channels 210 in the X-axis direction.

Here, the cavity sidewalls 232 are formed at an acute angle with respect to the backside 220 of the semiconductor device 204 such that upper portions of opposing (e.g., facing) cavity sidewalls 232 meet. Therefore, the cavity sidewalls 232 and the backside 220 of the semiconductor device 204 collectively define a triangular cross-section of the coolant channel 210.

In some embodiments, the backside 220 of the semiconductor device 204 comprises a corrosion protective layer (not shown). The corrosion protective layer may be a continuous layer disposed across the entire backside 220 of the semiconductor device 204, such that the cold plate 206 is attached thereto. Beneficially, the corrosion protective layer provides a corrosion-resistant barrier layer, thus preventing undesired corrosion of the semiconductor device 204 (e.g., the semiconductor substrate material which might otherwise be in direct contact with coolant fluid flowing through a coolant chamber volume 210).

One or more coolant chamber volumes may include one or more coolant channels. The coolant channels may extend between a single inlet opening and a single outlet opening of the cold plate 206, such that the coolant chamber volume(s) and/or coolant channel(s) share the same inlet and outlet openings. In some embodiments, multiple inlet and/or outlet openings may be coupled to the coolant chamber volume(s).

In embodiments having plural coolant chamber volumes and/or plural coolant channels, each coolant chamber volume and/or coolant channel may be connected between a separate inlet opening and a separate outlet opening. In such embodiments, the coolant fluid may be directed to the separate inlet openings and from the separate outlet openings using a manifold disposed above the openings in the Z-axis direction.

In some embodiments, a height in the Z-axis direction of the coolant chamber volume(s) and or coolant channel(s) may be greater than 100 μm, 100 μm-1000 μm, or 100 μm-700 μm. A width in the Y-axis direction of the coolant chamber volume(s) and/or coolant channel(s) may be greater than 100 μm, 100 μm-1000 μm, or 100 μm-700 μm. For example, the width of the coolant chamber volume(s) and/or coolant channel(s) may be greater than the height. A cross-section of the coolant chamber volume(s) and/or coolant channel(s) in the Y-Z plane is wide enough to allow for a pressure drop of 0-20 psi, 3-15 psi, or 4-10 psi.

In some embodiments, preparing a desired surface roughness of the sidewalls of the coolant chamber volume(s) and/or coolant channels may include depositing an organic layer on a photoresist layer after cold plate features have been etched to form a micro-masking layer, such as between 1 to 30 nm. The micro-masking layer may be dry etched to form the desired surface roughness, such as between 0.1 to 3.0 nm.

With reference to FIG. 3, the cold plate 206 is attached to the backside 220 of the device 204 without the use of an intervening adhesive. For example, the cold plate 206 may be directly bonded to the backside 220 of the device 204, such that the cold plate 206 and the backside 220 of the device 204 are in direct contact. For example, in some embodiments, one or both of the cold plate 206 and the backside 220 of the semiconductor device 204 may comprise a dielectric material layer, e.g., a first dielectric material layer 224A and a second dielectric material layer 224B respectively, and the cold plate 206 is directly bonded to the backside 220 of the semiconductor device 204 through bonds formed between the dielectric material layers 224A, 224B. In some embodiments, one of the cold plate 206 or the backside 220 of the semiconductor device 204 may comprise a thin bonding dielectric layer (e.g., silicon nitride, etc.) and other element(s) may not include any such explicit bonding dielectric layer (or can have only a native oxide layer). Here, the first and second dielectric material layers 224A, 224B are illustrated as continuous layers, but it will be understood that one or both of the layers may not be continuous. For example, the first dielectric material layer 224A may be disposed only on lower surfaces of the cold plate 206 facing the backside 220 of the semiconductor device 204. With reference to FIG. 4, described below, portions of the first dielectric material layer 224A may be disposed only on lower surfaces of support features 230. Beneficially, directly bonding the cold plate 206 to the semiconductor device 204, as described above, reduces the thermal resistance therebetween and increases the efficiency of heat transfer from the semiconductor device 204 to the cold plate 206. In particular, thermal resistance is reduced by directly bonding lower surfaces of the cavity dividers (e.g., the support features 230) facing the semiconductor device 204 to the backside 220 of the semiconductor device 204.

FIG. 4 is a schematic sectional view in the Y-Z plane of the integrated cooling assembly 203. In FIG. 4, the cold plate 206 comprises a patterned side that faces towards the semiconductor device 204 and an opposite side that faces towards the package cover 208 (not shown). The patterned side comprises a coolant chamber volume having plural coolant channels 210, which extend laterally between the inlet and outlet openings 106A of the cold plate 206. Each coolant channel 210 comprises cavity sidewalls that define a corresponding coolant channel 210. Portions of the cold plate 206 between the cavity sidewalls form support features 230. The support features 230 provide structural support to the integrated cooling assembly 203 and disrupt laminar fluid flow at the interface of the coolant and the device backside 220, resulting in increased heat transfer therebetween. Furthermore, by introducing plural coolant channels 210 to define separate coolant flow paths, an internal surface area of the cold plate 206 is increased, which further increases the efficiency of heat transfer.

In FIG. 4, arrows 228A and 228B illustrate two different heat transfer paths (respectively labeled heat transfer paths 228A, 228B) in the integrated cooling assembly 203. A first heat transfer path illustrated by arrow 228B shows heat generated by the semiconductor device 204 transferring directly from the semiconductor material of the semiconductor device 204 to coolant fluid flowing through the cold plate 206. A second heat transfer path illustrated by arrows 228A shows heat generated by the semiconductor device 204 being transferred from semiconductor material (e.g., silicon material) of the semiconductor device 204 to semiconductor material (e.g., silicon material) of the cold plate 206 structure, propagated throughout the semiconductor material of the cold plate 206 structure (shown as dashed lines), and being transferring into coolant fluid flowing through the cold plate 206. A thermal resistance of the first and second heat transfer paths 228A, 228B is illustrated by heat transfer path 228C, which is shown as thermal resistance R1 between a heat source and a cold plate. Here, R1 is the thermal resistance of the bulk semiconductor material of the semiconductor device 204. It can be seen that the heat transfer path 228C of the integrated cooling assembly 203 is reduced compared to the heat transfer path 26 of the device package 10 of FIG. 1, due to the direct bonding discussed above.

In some embodiments, the cold plate 206 may be attached to the semiconductor device 204 using a hybrid bonding technique, where bonds are formed between the dielectric material layers 224A, 224B (see FIG. 3) and between metal features, such as between first metal pads and second metal pads, disposed in the dielectric material layers 224A, 224B.

Suitable dielectrics that may be used as the dielectric material layers 224A, 224B include silicon oxides, silicon nitrides, silicon oxynitrides, silicon carbon nitrides, metal-oxides, metal-nitrides, silicon carbide, silicon oxycarbides, silicon oxycarbonitride, diamond-like carbon (DLC), or combinations thereof. In some embodiments, one or both of the dielectric material layers 224A, 224B are formed of an inorganic dielectric material, e.g., a dielectric material substantially free of organic polymers. Typically, one or both of the dielectric layers are deposited to a thickness greater than the thickness of a native oxide, such as about 1 nanometer (nm) or more, 5 nm or more, 10 nm or more, 50 nm or more, or 100 nm or more. In some embodiments, one or both of the layers are deposited to a thickness of 3 micrometers or less, 1 micrometer or less, 500 nm or less, such as 100 nm or less, or 50 nm or less. The dielectric layer material and thickness may be optimized for lower thermal resistance between the die and the cold plate. For example, a first dielectric material layer comprising native oxide, the first dielectric material layer having a thickness in the Z-direction of about 1 nm to about 5 nm, may be disposed on a semiconductor substrate (e.g., silicon). The first dielectric material layer comprising the native oxide may be directly bonded to a second dielectric material layer comprising a same or different dielectric material, the second dielectric material layer having a thickness in the Z-direction of about 1 nm to about 5 nm. That is, a bonding layer comprising native oxide may be bonded to another bonding layer comprising a native oxide or another dielectric material.

The cold plate 206 may be formed of any suitable material that has sufficient structural strength to withstand the desired pressures of coolant flowing into the coolant chamber volume 210. For example, the cold plate 206 may be formed of semiconductor material like silicon or other engineered materials like glass. In other examples, the cold plate 206 may be formed of a material selected from a group comprising polymers, metals, ceramics, or composites thereof. In some embodiments, the cold plate 206 may be formed of stainless steel (e.g., from a stainless-steel metal sheet) or a sapphire plate.

In some embodiments, the cold plate 206 may be formed of a bulk material having a substantially similar coefficient of linear thermal expansion (CTE) to the bulk material of the substrate 202 and/or the semiconductor device 204, where the CTE is a fractional change in length of the material (in the X-Y plane) per degree of temperature change. In some embodiments, the CTEs of the cold plate 206, the substrate 202, and/or the semiconductor device 204 are matched so that the CTE of the substrate 202 and/or the semiconductor device 204 is within about +/−20% or less of the CTE of the cold plate 206, such as within +/−15% or less, within +/−10% or less, or within about +/−5% or less when measured across a desired temperature range. In some embodiments, the CTEs are matched across a temperature range from about-60° C. to about 100° C. or from about −60° C. to about 175° C. In one example embodiment, the matched CTE materials each include silicon.

In some embodiments, the cold plate 206 may be formed of a material having a substantially different CTE from the semiconductor device 204, e.g., a CTE mismatched material. In such embodiments, the cold plate 206 may be attached to the semiconductor device 204 by a compliant adhesive layer (not shown) or a molding material that absorbs the difference in expansion between the cold plate 206 and the semiconductor device 204 across repeated thermal cycles.

The package cover 208 shown in FIGS. 2C and 3 generally comprises one or more vertical or sloped sidewall portions 208A and a lateral portion 208B that spans and connects the sidewall portions 208A. The sidewall portions 208A may extend upwardly from a peripheral surface of the package substrate 202 to surround the device 204 and the cold plate 206 disposed thereon. The lateral portion 208B may be disposed over the cold plate 206 and is typically spaced apart from the cold plate 206 by a gap corresponding to the thickness of the sealing material layer 222. Coolant is circulated through the coolant chamber volume 210 through the inlet and outlet openings 212 of the package cover 208 formed through the lateral portion 208B. The inlet and outlet openings 206A of the cold plate 206 may be in fluid communication with the inlet and outlet openings 212 of the package cover 208 through the inlet and outlet openings 222A formed in the sealing material layer 222 disposed therebetween. In certain embodiments, coolant lines 108 (FIGS. 2A-2B) may be attached to the device package 201 by use of connector features formed in the package cover 208, such as threads formed in the sidewalls of the inlet and outlet openings 212 of the package cover 208 and/or protruding features 214 that surround the inlet and outlet openings 212 and extend upwardly from a surface of the lateral portion 208B.

Typically, the package cover 208 is formed of semi-rigid or rigid material so that at least a portion of the downward force exerted on the package cover 208 by the mounting frame is transferred to a supporting surface of the package substrate 202 and not transferred to the cold plate 206 and the semiconductor device 204 therebelow. In some embodiments, the package cover 208 is formed of a thermally conductive metal, such as aluminum or copper. In such embodiments, the package cover 208 functions as a heat spreader that redistributes heat from one or more electronic components of the semiconductor device 204.

It should be noted that the direction in which the coolant fluid flows through the cold plate 206 may be controlled depending on the relative locations of the inlet and outlet openings. For example, the coolant fluid may flow from left to right in the device package 201 of FIG. 3 when the inlet openings 212, 222A, 206A of the package cover 208, the sealing material layer 222, and the cold plate 206, respectively, are located on the left-hand side of the device package 201 and the outlet openings 212, 222A, 206A of the package cover 208, the sealing material layer 222, and the cold plate 206, respectively, are located on the right-hand side of the device package 201. Alternatively, the coolant fluid may flow from right to left in the device package 201 illustrated in FIG. 3 when the outlet openings 212, 222A, 206A of the package cover 208, the sealing material layer 222, and the cold plate 206 are located on the left-hand side of the device package 201 and the inlet openings 212, 222A, 206A of the package cover 208, the sealing material layer 222, and the cold plate 206 are located on the right-hand side of the device package 201. Although only one set of inlet and outlet openings is shown and described here, additional inlet and outlet openings may also be provided at various locations on the package cover 208, the sealing material layer 222, and the cold plate 206.

An example flow path of the coolant fluid through the coolant chamber volume 210 may be as follows:
1. Coolant fluid enters the coolant chamber volume 210 through the inlet openings.
2. Coolant fluid flows across the inside surfaces of the cold plate 206 and absorbs heat generated by the semiconductor device 204, which has dissipated into the cold plate 206 structure. The coolant fluid may also flow directly across the backside 220 of the semiconductor device 204 to absorb heat energy directly from the semiconductor device 204. The coolant chamber volume 210 may additionally have various channels formed to direct the coolant fluid flow from inlet opening(s) to outlet opening(s) and facilitate heat extraction from the semiconductor device 204 by the coolant fluid. In some embodiments, the coolant fluid may be in direct contact with the backside 220 of the semiconductor device 204 or via one or more substrate or layers between the coolant fluid or backside 220 of the semiconductor device 204.
3. Coolant fluid exits the coolant chamber volume 210 through outlet openings.

It will be understood from the above flow path that heat is extracted without introducing an unnecessary thermal resistance (e.g., a TIM disposed between the backside 220 of the semiconductor device 204 and the cold plate 206) between the backside 220 of the semiconductor device 204 and the cold plate 206.

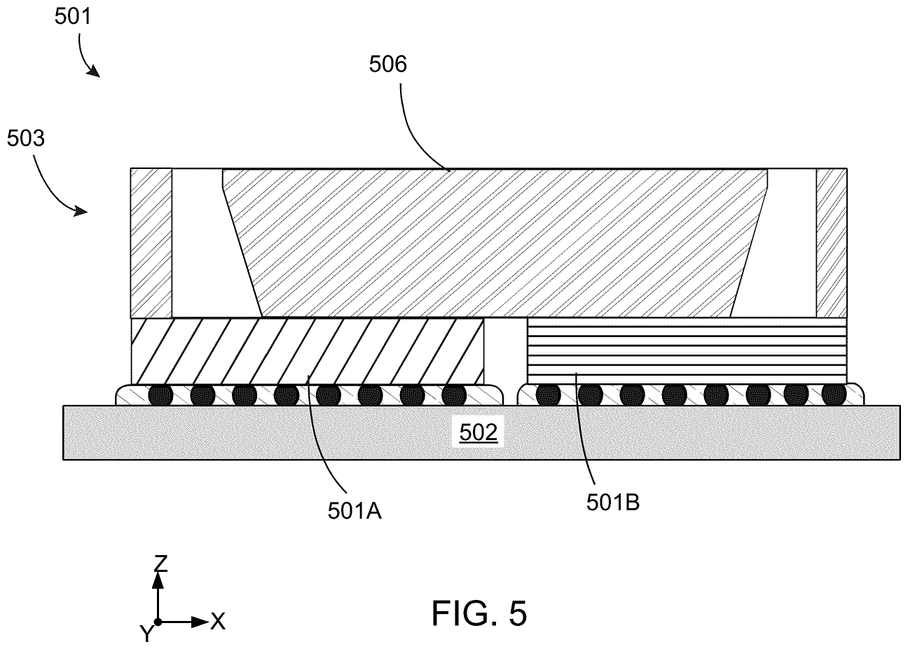

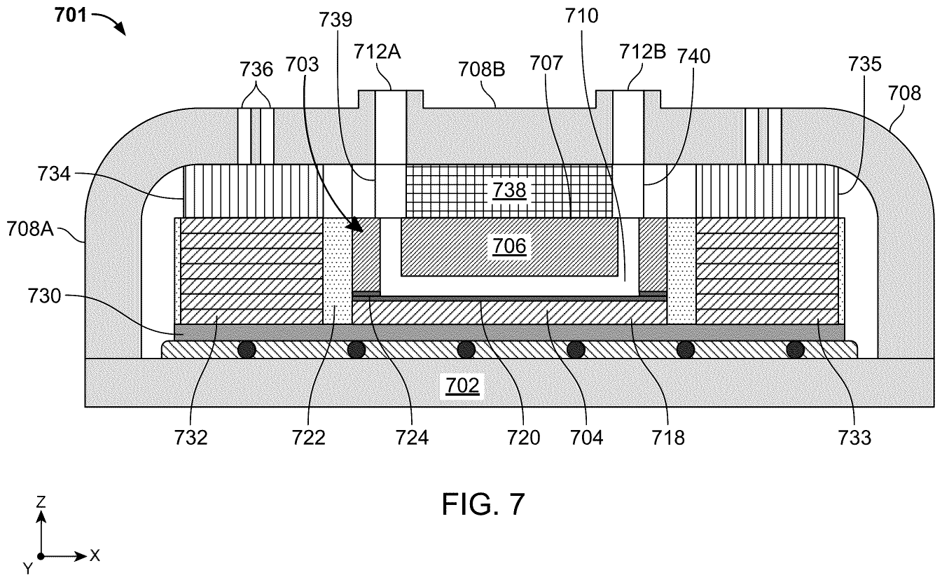

FIG. 5 is a schematic side sectional view in the X-Z plane of an example of a multi-component device package 501 that includes a cold plate 506 directly bonded to the backside surfaces of two or more devices 501A, 501B. The multi-component device package 501 may be similar to the device package 201 described above, and therefore the description of similar features is omitted for brevity. In some embodiments, the two or more devices 501A and 501B are reconstituted and then bonded to the cold plate 506. As shown, the device package 501 includes a package substrate 502 and an integrated cooling assembly 503. In some other embodiments, a package cover (not shown) may be disposed on a periphery of the package substrate 502 with a sealing material layer disposed between the package cover and the integrated cooling assembly 503 as described with respect to FIGS. 7-15. The integrated cooling assembly 503 may include a plurality of devices 501A (one shown) that may be singulated and/or disposed in a vertical device stack 501B (one shown). The cold plate 506 may be attached to each of the devices 501A and device stack 501B, e.g., by the direct bonding methods described herein or other methods including flip chip bonding, etc. In some embodiments, the device 501A may comprise a processor, and the device stack 501B may comprise a plurality of memory devices. Here, the device 501A and the device stack 501B are disposed in a side-by-side arrangement on the package substrate 502 and are in electrical communication with one another through conductive elements formed in, on, or through the package substrate 502. Here, the cold plate 506 is sized to provide a bonding surface for attachment to both the device 501A and the device stack 501B but may otherwise be the same or substantially similar to other cold plates described herein. In some embodiments, the lateral dimensions (or footprint) of the cold plate 506 may be smaller or larger than the combined lateral dimensions (or footprint) of both the device 501A and the device stack 501B. In some embodiments, one or more sidewalls of the cold plate 506 may be aligned or offset to the vertical sidewalls of the device 501A and the device stack 501B (including inside or outside their footprint). In some embodiments, more than one cold plate 506 may be bonded. For example, separate cold plates may be bonded to the device 501A and the device stack 501B.

In some embodiments, the package substrate 502 may include or be an interposer. That is, the two or more devices 501A, 501B may be micro-bump bonded on an interposer using conductive bumps, such the conductive bumps 219, and molded to form an assembly, where the cold plate 506 is bonded to the respective backsides of the two or more devices 501A, 501B. The assembly may be flip chip bonded to a substrate, such as an organic substrate. It is contemplated that mounting the device and/or other components to a package substrate, an interposer, etc., may include depositing a reflowable conductive material, such as conductive balls or bumps, coined solder balls, and other variants, for forming interconnections as described with respect to FIG. 7.

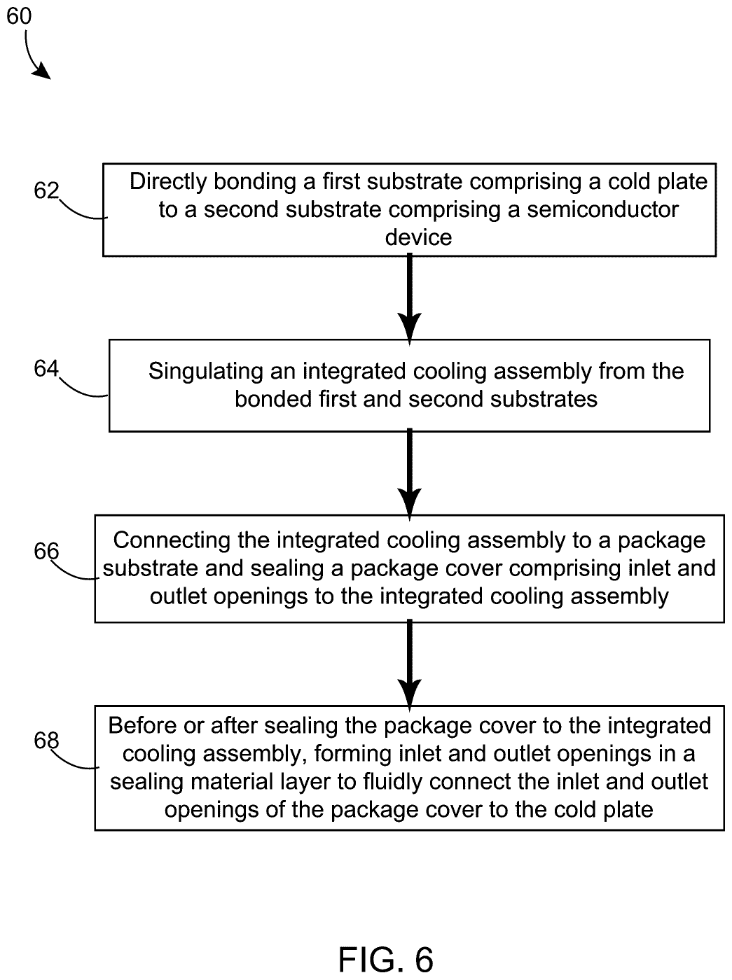

FIG. 6 is a flow diagram showing a method 60 of forming an integrated cooling assembly, in accordance with embodiments of the present disclosure. Generally, the method 60 includes bonding a first substrate comprising one or more cold plates 206 to a second substrate comprising one or more semiconductor devices 204, and singulating one or more integrated cooling assemblies 203 from the bonded first and second substrates. For example, a wafer (bare or reconstituted wafer) comprising one or more cold plates 206 can be directly bonded to another wafer (bare or reconstituted wafer) comprising one or more semiconductor devices 204.

It will be understood that the first substrate may be a cold plate die or part of a wafer of cold plates. Further, the second substrate may be a semiconductor device die or part of a wafer of semiconductor devices 204. Therefore, the method 60 may include die-to-die direct bonding (e.g., cold plate die to semiconductor device die), water-to-die direct bonding (e.g., cold plate die to semiconductor device wafer, or cold plate wafer to semiconductor device die), and wafer-to-wafer direct bonding (e.g., cold plate wafer to semiconductor device wafer). It will be understood that the singulation step (discussed in relation to block 64, below) may not be required for a die-to-die direct bonding operation.

For simplicity, the following description is focused on forming one integrated cooling assembly 203 comprising one cold plate 206 and one semiconductor device 204. However, as mentioned above, in some embodiments, the first substrate may comprise plural cold plates 206 and the second substrate may comprise plural semiconductor devices 204, such that plural integrated cooling assemblies 203 may be formed from the first and second substrates.

At block 62, the method 60 includes directly bonding the first substrate (e.g., a monocrystalline silicon wafer) comprising a cold plate 206 to the second substrate (e.g., a monocrystalline silicon wafer) comprising a semiconductor device 204 without an intervening adhesive.

In some embodiments, the first substrate may be etched using a patterned mask layer formed on its surface to form features of the cold plate 206. An anisotropic etch process may be used, which uses inherently differing etch rates for the silicon material as between {100} plane surfaces and {111} plane surfaces when exposed to an anisotropic etchant.

In some embodiments, the etching process is controlled to where the etch rates of the substrate surfaces have a ratio between about 1:10 and about 1:200, such as between about 1:10 and about 1:100, for example between about 1:10 and 1:50, or between about 1:25 and 1:75. Examples of suitable anisotropic wet etchants include aqueous solutions of potassium hydroxide (KOH), ethylene diamine and pyrocatechol (EPD), ammonium hydroxide (HN₄OH), hydrazine (N₂H₄), or tetra methyl ammonium hydroxide (TMAH). The actual etch rates of the silicon substrate depend on the concentration of the etchant in the aqueous solution, the temperature of the aqueous solution, and a concentration of the dopant in the substrate (if any). Typically, the mask layer is formed of a material that is selective to anisotropic etch compared to the underlying monocrystalline silicon substrate. Examples of suitable mask materials include silicon oxide (SiₓO_{y}) or silicon nitride (SiₓN_{y}). In some embodiments, the mask layer has a thickness of about 100 nm or less, such as about 50 nm or less, or about 30 nm or less. The mask layer may be patterned using any suitable combination of lithography and material etching patterning methods.

The second substrate may include a bulk material, and a plurality of material layers disposed on the bulk material. The bulk material may include any semiconductor material suitable for manufacturing semiconductor devices, such as silicon, silicon carbide, silicon germanium, germanium, group III-V semiconductor materials, group II-VI semiconductor materials, or combinations thereof. While some high-performance processors like CPUs, GPUs, neural processing units (NPUs), and tensor processing units (TPUs) are typically made out of silicon, some other high power density (hence substantial heat-generating) devices may comprise silicon carbide or gallium nitride, for example. In some embodiments, the second substrate may include a monocrystalline wafer, such as a silicon wafer, a plurality of device components formed in or on the silicon wafer, and a plurality of interconnect layers formed over the plurality of device components. In other embodiments, the second substrate may comprise a reconstituted substrate, e.g., a substrate formed from a plurality of singulated devices embedded in a support material. In some embodiments, each semiconductor device may have its own individual cold plate fabricated through a reconstitution process.

The bulk material of the second substrate may be thinned after the semiconductor device 204 is formed using one or more backgrinding, etching, and polishing operations that remove material from the backside. Thinning the second substrate may include using a combination of grinding and etching processes to reduce the thickness (in the Z-direction) to about 450 μm or less, such as about 200 μm or less, or about 150 μm or less or about 50 μm or less. After thinning, the backside 220 may be polished to a desired smoothness using a chemical mechanical polishing (CMP) process, and the dielectric material layer may be deposited thereon. In some embodiments, the dielectric material layer may be polished to a desired smoothness to prepare the second substrate for the bonding process. In some embodiments, the method 60 includes forming a plurality of metal features in the dielectric material layer in preparation for a hybrid bonding process, such as by use of a damascene process.

In some embodiments, the active side of the second substrate is temporarily bonded to a carrier substrate (not shown) before or after the thinning process. When used, the carrier substrate provides support for the thinning operation and/or for the thinned material to facilitate substrate handling during one or more of the subsequent manufacturing operations described herein.

Here, the method 60 may include forming dielectric layers on one or both the first and second substrates, and directly bonding includes forming dielectric bonds between a first dielectric material layer of the first substrate and a second dielectric material layer of the second substrate (or forming dielectric bonds between one substrate and a dielectric material layer of the other substrate). Direct bonding processes join dielectric layers by forming strong chemical bonds (e.g., covalent bonds) between the dielectric layers.

Generally, directly bonding the surfaces (of the dielectric material layers formed on the first and second substrates) includes preparing, aligning, and contacting the surfaces. Examples of dielectric material layers include silicon oxide, silicon nitride, silicon oxynitride, and silicon carbonitride. Preparing the surfaces may include smoothing the respective surfaces to a desired surface roughness, such as between 0.1 to 3.0 nm RMS, activating the surfaces to weaken or open chemical bonds in the dielectric material, and terminating the surfaces with a desired species. Smoothing the surfaces may include polishing the first and second substrates using a CMP process. Activating and terminating the surfaces with a desired species may include exposing the surfaces to radical species formed in a plasma. The bond interface between the bonded dielectric layers can include a higher concentration of materials from the activation and/or last chemical treatment processes compared to the bulk of the bonding layers. For example, in some embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between nonconductive bonding surfaces.

In some embodiments, the plasma is formed using a nitrogen-containing gas, e.g., N₂, and the terminating species includes nitrogen, or nitrogen and hydrogen. In some embodiments, fluorine may also be present within the plasma. In some embodiments, the surfaces may be activated using a wet cleaning process, e.g., by exposing the surfaces to an aqueous ammonia solution. In some embodiments, the dielectric bonds may be formed using a dielectric material layer deposited on only one of the first and second substrates, but not on both. In those embodiments, the direct dielectric bonds may be formed by contacting the deposited dielectric material layer of one of the first and second substrates directly with a bulk material surface (or such a surface with a native oxide) of the other substrate.

Directly forming direct dielectric bonds between the first and second substrates at block 62 may include bringing the prepared and aligned surfaces into direct contact at a temperature less than 150° C., such as less than 100° C., for example, less than 30° C., or about room temperature, e.g., between 20° C. and 30° C. Without intending to be bound by theory, in the case of directly bonding surfaces terminated with nitrogen and hydrogen (e.g., NH₂ groups), it is believed that the hydrogen terminating species diffuse from the interfacial bonding surfaces, and chemical bonds are formed between the remaining nitrogen species during the direct bonding process. In some embodiments, the direct bond is strengthened using an anneal process, where the substrates are heated to and maintained at a temperature of greater than about 30° C. and less than about 450° C., for example, greater than about 50° C. and less than about 250° C., or about 150° C., for a duration of about 5 minutes or more, such as about 15 minutes. Typically, the bonds will strengthen over time even without the application of heat. Thus, in some embodiments, the method does not include heating the substrates.

In embodiments where the first and second substrates are bonded using hybrid dielectric and metal bonds, the method 60 may further include planarizing or recessing the metal features below the dielectric field surface before contacting and bonding the dielectric material layers. After the dielectric bonds are formed, the first and second substrates may be heated to a temperature of 150° C. or more and maintained at the elevated temperature for a duration of about 1 hour or more, such as between 8 and 24 hours, to form direct metallurgical bonds between the metal features.

Suitable direct dielectric and hybrid bonding technologies that may be used to perform aspects of the methods described herein include ZiBond® and DBI®, each of which are commercially available from Adeia Holding Corp., San Jose, CA, USA.

At block 64, the method 60 includes singulating at least one integrated cooling assembly 203 from the bonded first and second substrates. Singulation after bonding may impart distinctive structural characteristics on the integrated cooling assembly 203 as the bonding surface of the cold plate 206 has the same perimeter as the backside of the semiconductor device 204 bonded thereto. Thus, the sidewalls (e.g., side surfaces) of the cold plate 206 are typically flush with the edges (e.g., side surfaces) of the semiconductor device 204 about their common perimeters. In some embodiments, the cold plate 206 is singulated from the first substrate using a process that cuts or divides the first substrate in a vertical plane, i.e., in the Z-direction. In those embodiments, the side surfaces of the cold plate 206 are substantially perpendicular to the backside 220 of the semiconductor device 204, i.e., a horizontal (X-Y) plane of an attachment interface between the semiconductor device 204 and the cold plate 206. In some embodiments, the cold plate 206 is singulated using a saw or laser dicing process.

At block 66, the method 60 may include connecting the integrated cooling assembly 203 to the package substrate 202 and sealing a package cover 208 comprising inlet and outlet openings 212 to the integrated cooling assembly 203 by use of a molding compound that, when cured, forms a sealing material layer 222.

At block 68, the method 60 may include, before or after sealing the package cover 208 to the integrated cooling assembly 203, forming inlet and outlet openings 222A in the sealing material layer 222 to fluidly connect the inlet and outlet openings 212 of the package cover 208 to the cold plate 206.

The following FIGS. and corresponding description refer to sectional views in the X-Z plane, for example, as described with respect to FIGS. 1, 2B, 3, and 5 unless otherwise noted. FIG. 7 shows a schematic sectional view of a device package 701 including a cooling apparatus attached to a package substrate 702. Referring to FIG. 3, in some embodiments, the cooling apparatus may be disposed on an underfill layer, such as the underfill layer 221, having conductive bumps, such as the conductive bumps 219. The cooling apparatus includes an integrated cooling assembly 703. Here, the integrated cooling assembly 703 includes a cold plate 706 and a first die 704. The cold plate 706 includes a first cold plate portion and a second cold plate portion. The cold plate 706 is attached to the first die 704. That is, the first cold plate portion may be directly bonded to a backside of the first die. The second cold plate portion is spaced apart from the backside of the first die. Here, the cold plate 706 includes a first cold plate side, such as a cold plate frontside, facing towards the package substrate 702, and a second cold plate side opposite the first cold plate side, such as a cold plate backside 707, facing away from the package substrate 702. The first die includes a first die side, such as a die backside 720, and a second die side opposite to the first die side, such as an active side 718. Here, a channel volume 710 is defined between at least a portion of the cold plate frontside and the die backside 720. That is, the cold plate frontside, or at least the portion thereof, is spaced apart from the die backside 720 to define the channel volume 710. The channel volume 710 includes an inlet portion 706A and an outlet portion 706B disposed at the cold plate backside 707. Here, the inlet portion 706A and the outlet portion 706B are open at the cold plate backside 707. The inlet portion and the outlet portion may be fluidly coupled to a package cover 708.

The first cold plate portion may include or be a perimeter sidewall. The second cold plate portion may include or be a top portion of the cold plate. The cold plate 706 may include one or more cavity dividers (e.g., support features 230) comprising cavity sidewalls. The perimeter sidewall extends downwardly from the top portion of the cold plate 706 to the die backside 720 of the first die 704 to define a perimeter of the cold plate 706. The one or more cavity dividers extend downwardly from the top portion of the cold plate 706 towards the die backside 720 of the first die 704. The cavity sidewalls, the perimeter sidewall, and the die backside 720 of the first die 70 collectively define the channel volume 710 therebetween.

The integrated cooling assembly 703 is attached to an interposer. Here, the integrated cooling assembly 703 is bonded to an interposer 730. That is, a side of the first die 704, such as the active side 718, may be directly bonded to the interposer 730. In some embodiments, the integrated cooling assembly 703 is flip chip bonded or micro-bump bonded to the interposer 730. The cooling apparatus may include one or more second dies communicatively coupled to the first die 704 through the interposer 730. Here, the cooling apparatus includes a plurality of second dies disposed on the interposer 730. The plurality of second dies including second dies 732, 733 is disposed over the package substrate 702 and adjacent to the integrated cooling assembly 703. Here, a left second die 732 is disposed adjacent to a left side of the integrated cooling assembly 703 in the X-direction, and a right second die 733 is disposed adjacent to a right side of the integrated cooling assembly 703 in the X-direction. The second dies 732, 733 may be directly bonded to the interposer 730. In some embodiments, one or both of the second dies 732, 733 are flip chip bonded or micro-bump bonded to the interposer 730. The device package 701 includes the package cover 708 attached to a periphery of the package substrate 702. The package cover 708 includes sidewall portions 708A extending upwardly from the periphery of the package substrate 702 and a lateral portion 708B that spans and connects the sidewall portions 708A. The lateral portion 708B may be disposed over the cooling apparatus. That is, the lateral portion 708B laterally extends between the sidewall portions 708A over the integrated cooling assembly 703 and the second dies 732, 733. Here, the package cover 708 includes inlet opening 712A and outlet opening 712B disposed through the lateral portion 708B over the integrated cooling assembly 703. The package cover 708 may include one or more openings disposed over the second dies 732, 733. In some embodiments, the package cover 708 and one or both second dies 732, 733 are thermally attached by a TIM layer disposed between the package cover 708 and a respective second die, such as between the package cover 708 and the left second die 732 and/or between the package cover 708 and the right second die 733.

The one or more second dies communicatively coupled to the first die 704 through the interposer 730 may include a die stack. Here, the second dies 732, 733 may be die stacks, such as memory dies. In some embodiments, the first die 704 comprises logic (e.g. CPU, GPU, NPU, TPU, DPU, etc.), and one or more of the plurality of second dies, such as the second dies 732, 733, comprise high-bandwidth memory (HBM). The first die 704 may be communicatively coupled to each of the plurality of second dies. That is, attaching the integrated cooling assembly 703 to the interposer 730 forms interconnections between the first die 704 and each of the second dies 732, 733. The active side 718 may include one or more components that are electrically connected to one or more memories of the plurality of second dies. Here, the active side 718 is connected to each of the second dies 732, 733 through the interconnections disposed in the interposer 730. The active side 718 of the first die 704 may be directly bonded to the interposer 730, wherein the bonds between the first die 704 and the interposer 730 form the interconnections between the active side 718 and each of the second dies 732, 733.

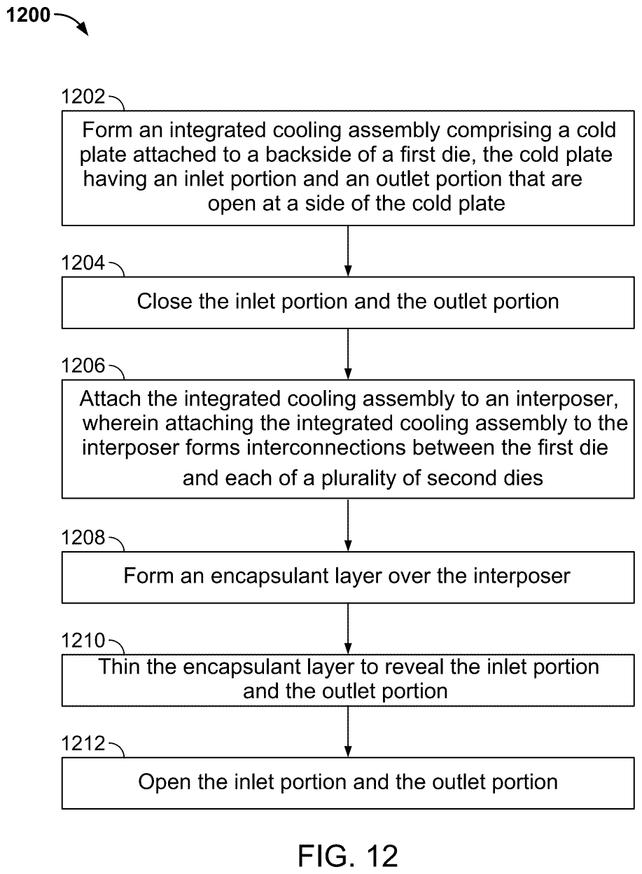

Here, a thickness of the integrated cooling assembly 703 in the Z-direction orthogonal to the die backside 720 is about the same as a thickness of at least one of the second dies 732, 732 in the Z-direction. In some embodiments, the second dies 732, 733 may be a die stack having an overall thickness in the Z-direction. The thickness of the integrated cooling assembly 703 may be about the same as the overall thickness of the die stack in the same direction. The thickness of the integrated cooling assembly 703 may be different than a thickness of each die of the die stack in the Z-direction. In some embodiments, a thickness of the integrated cooling assembly 703 in a direction orthogonal to the die backside 720 is different than a thickness of at least one second die of the plurality of second dies in the same direction as described with respect to FIGS. 12-15. That is, the thickness of the integrated cooling assembly 703 in the Z-direction may be less than the thickness of at least one second die of the plurality of second dies in the same direction. Here, the left second die 732 has a same thickness in the Z-direction as the right second die 733. In some embodiments, one or more dies and/or die stacks having different overall thicknesses are communicatively coupled to the first die through an interposer. That is, a thickness of at least one die of the plurality of second dies in the direction orthogonal to the die backside 720 is different than another die of the plurality of second dies. A third die (not shown) may be communicatively coupled to the first die 704 through the interposer 730, where the thickness of the third die in the Z-direction orthogonal to the backside 720 of the first die 704 may be different than the thickness of another die coupled to the first die 704 through the interposer 730, such as the left second die 732 and/or the right second die 733.

It is contemplated that interconnections between the first die 704, one or more of the plurality of second dies, and/or the interposer 730 may be formed using various interconnect techniques and combinations thereof, such as micro-bump bonding, flip chip bonding, etc. In some embodiments, one or more devices may include conductive bumps disposed between a device and an interposer, such as solder bumps, such as microbumps. That is, any of the first die 704 and/or the plurality of second dies may be attached to a first side of the interposer 730, here an upper Z-direction side of the interposer 730, using micro-bump bonding and/or flip chip bonding. The interconnections between the first die 704 and/or the plurality of second dies are formed through connections between a respective die and the interposer 730 using the conductive bumps, such as microbumps between the first die 704 and the first side of the interposer 730 and/or microbumps between any of the second dies 732, 733 and the first side of the interposer 730.

Attaching one or more devices to an interposer may include micro-bump bonding, flip chip bonding, and/or variants thereof, and/or combinations thereof. Attaching the first die 704 and the plurality of second dies to the interposer may form an assembly. The assembly may be flip chip bonded to a substrate, such as the package substrate 702. That is, a conductive reflowable material, such as solder, may be deposited on interconnects disposed at a second side of the interposer 730, here a lower Z-direction side of the interposer 730, which is opposite to the first side of the interposer 730. The assembly may be flipped and positioned over the substrate. The assembly is positioned such that the second side of the interposer faces towards and is attached to the substrate. The conductive reflowable material may be reflowed, such as using hot air reflow, to form connections between the interposer 730 and the substrate and to form connections between the first die 704, any of the plurality of second dies, and the substrate through the interposer 730.

The cold plate 706 is attached to a backside of the first die 704. Here, the cold plate 706 is directly bonded to a backside of the first die 70. In some embodiments, the cold plate 706 is attached to the backside of the first die 704 by direct dielectric bonds or direct hybrid bonds. Here, at least a portion of the cold plate 706 is directly bonded to the die backside 720. That is, a perimeter sidewall of the cold plate 706 may be bonded to the die backside 720. Referring to FIGS. 3-4, the cold plate frontside, or a portion thereof, may be patterned such as the patterned side of the cold plate 206, where the patterned side includes one or more cavity dividers (e.g., the support features 230). One or more of the cavity dividers may be bonded to the die backside 720. In some embodiments, the cold plate 706 and/or the first die 704 include one or more dielectric layers, such as a dielectric layer 724. Here, the die backside 720 includes the dielectric layer 724. In some embodiments, one or both of the cold plate 706 and the die backside 720 may include the one or more dielectric layers. Here, the cold plate 706 may be directly bonded to the die backside 720 through bonds formed between the cold plate frontside and the dielectric layer 724. Beneficially, the dielectric layer 724 may protect the die backside 720, such as from undesired corrosion of the semiconductor substrate material of the first die 704 which might otherwise be in direct contact with a coolant fluid flowing through the channel volume 710.

It is noted that one of the cold plate 706 or the backside 720 of the first die 704 may comprise one or more bonding layers (e.g., comprising a dielectric material such as silicon nitride, etc.), and other element(s) may not include any such explicit bonding dielectric layer (or can have only a native oxide layer). Here, the dielectric layer 724 is illustrated as non-continuous. That is, the dielectric layer 724 may include dielectric material portions disposed on lower Z-direction surfaces of the cold plate 706, such as a perimeter sidewall of the cold plate 706 and/or cavity dividers (not shown). It will be understood that the one or more dielectric layers may be continuous. That is, the dielectric material portions disposed on lower surfaces of the cold plate 706 may be part of a bonding layer disposed on at least a portion of the cold plate 706. The dielectric layer 724 may include a portion that extends along a perimeter of the cold plate 706 in the X-Y plane, such as between the perimeter sidewalls of the cold plate 706 and the die backside 720 of the first die 704.

An encapsulant layer 722 extends upwardly from the interposer 730. The encapsulant layer 722 surrounds and/or encapsulates at least sidewall portions of the integrated cooling assembly 703 and each of the second dies 732, 733. Referring to FIG. 3, the encapsulant layer 722 may correspond to the sealing material layer 222. That is, the encapsulant layer 722 may comprise a polymer, epoxy, molding compound, or other material that forms a coolant fluid impermeable barrier. In some embodiments, one or more heat dissipation devices are disposed on the plurality of second dies. Here, a first heat dissipation device 734 is disposed on the left second die 732, and a second heat dissipation device 735 is disposed on the right second die 733. A manifold 738 is disposed on the integrated cooling assembly 703. Here, the manifold 738 is disposed between the cold plate backside 707 and the lateral portion 708B. The manifold 738 includes a manifold inlet channel 739 and a manifold outlet channel 740 in fluid communication with the inlet opening 712A and the outlet opening 712B of the package cover 708 and with the inlet portion 706A and the outlet portion 706B of the cold plate 706.

A thickness of the encapsulant layer 722 along a direction orthogonal to the die backside 720 may be about the same as a thickness of each of the plurality of second dies. Here, the thickness of the encapsulant layer 722 along the Z-direction is about the same as the thickness of each of the second dies 732, 733 along the Z-direction. That is, the encapsulant layer 722 may have been thinned to have about the same thickness as the second dies 732, 733 along the Z-direction, revealing an upper portion of the second dies 732, 733 and/or the integrated cooling assembly 703. The encapsulant layer 722 may form a coolant fluid impermeable barrier that prevents leaking of coolant fluid outside of the integrated cooling assembly 703. In some embodiments, the encapsulant layer 722 and the interposer 730 are singulated. That is, sidewalls of the encapsulant layer 722 and the interposer 730 may collectively form a sidewall of the cooling apparatus that is substantially planar.

A coolant fluid may be circulated through the channel volume 710 by way of the manifold channels 739, 740 disposed through the manifold 738. Here, a fluid path is collectively formed from the channels in fluid communication, starting from the inlet opening 712A, to the manifold inlet channel 739, and into the inlet portion of the channel volume 710. The fluid path continues through the outlet portion of the channel volume 710 to the manifold outlet channel 740 and out of the outlet opening 712B.

Each of the first die 704 and the plurality of second dies, such as the second dies 732, 733, may be arranged for cooling using different coolant fluids. Here, the first die 704 may be arranged for cooling by a coolant fluid delivered to the channel volume 710 and the cold plate 706 as described with respect to FIG. 4. In some embodiments, the heat dissipation devices 734, 735 are attached to their respective second die. The lateral portion 708B may be disposed on the heat dissipation devices 734, 735. In some embodiments, the package cover 708 is spaced apart from the heat dissipation devices 734, 735.

In some embodiments, the package cover 708 includes openings disposed through a portion of the package cover 708. The openings may be arranged for cooling the plurality of second dies, e.g., using a gaseous or liquid coolant. Here, airflow openings 736 are disposed through the lateral portion 708B, positioned over the first heat dissipation device 734 disposed on the left second die 732 and positioned over the second heat dissipation device 735 disposed on the right second die 733. The airflow openings 736 are arranged for a gaseous coolant that may be delivered to the heat dissipation devices 734, 735 and/or the second dies 732, 733 through forced or natural convection. In some embodiments, the openings disposed over the plurality of second dies are arranged for liquid cooling the plurality of second dies. The heat dissipation devices 734, 735 may be cold plates analogous to the cold plate 706. In some embodiments, heat dissipation devices are not disposed on the second dies 732, 733. That is, the upper portion of each of the second dies 732, 733 may be spaced apart from the lateral portion 708B by a respective gap through which a gaseous coolant may flow. The upper portion of the second dies 732, 733 may provide an interface between a gaseous coolant from the airflow openings 736 and the second dies 732, 733. It is appreciated that the openings 712A, 712B, and 736 in the package cover 708 are intended to be illustrative and non-limiting. It is contemplated that the package cover 708 may include any number of openings of any size or shape within the principles set forth in the present disclosure.

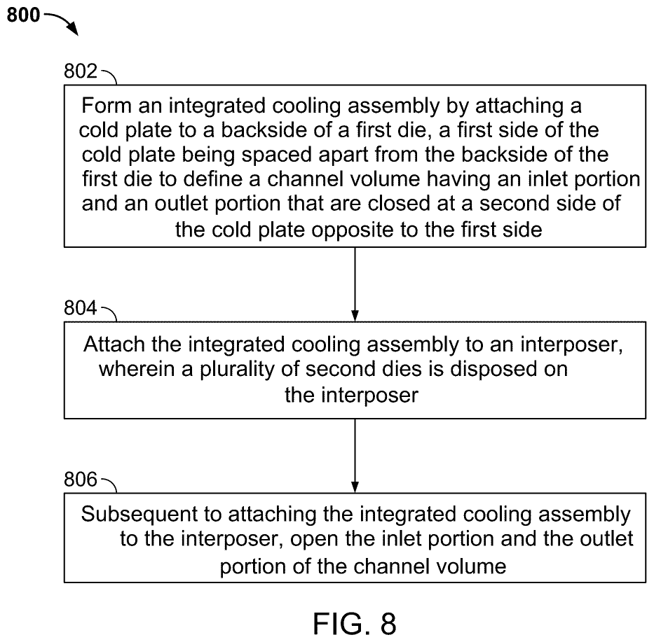

The following paragraphs refer to processes and example structures in manufacturing one cooling apparatus for illustrative purposes, but it is noted that any number of cooling apparatuses may be manufactured, such as in batch processes, as shown in FIGS. 8-15 and as described within the principles of the present disclosure. It is appreciated that wafer-to-wafer, die-to-wafer, and die-to-die processes may be included within the principles of the present disclosure.

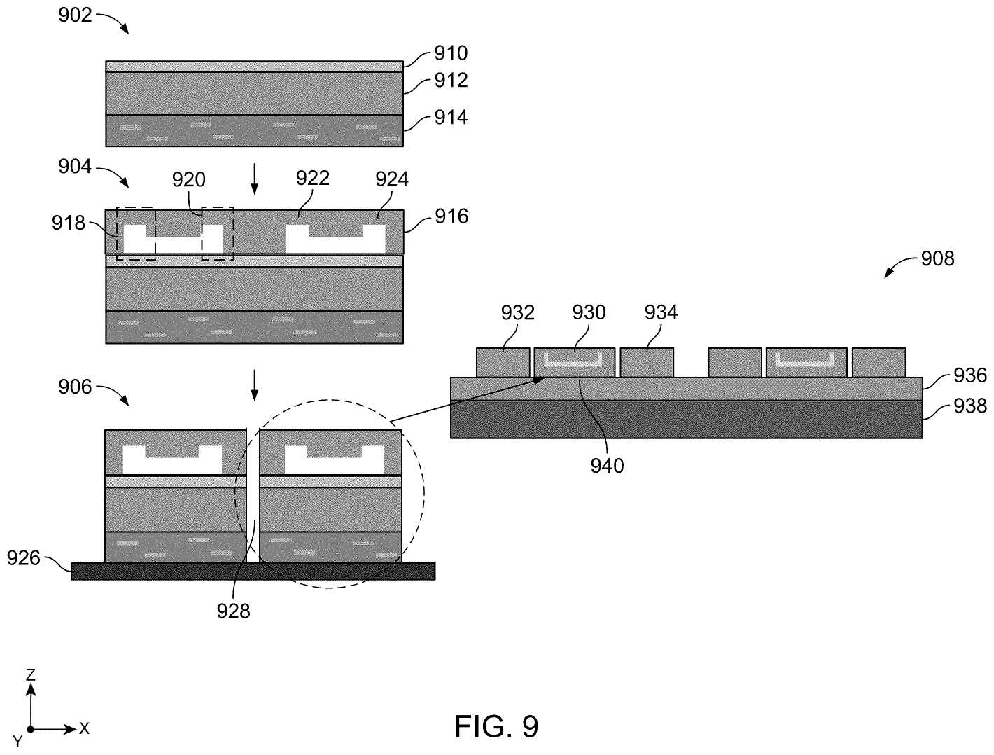

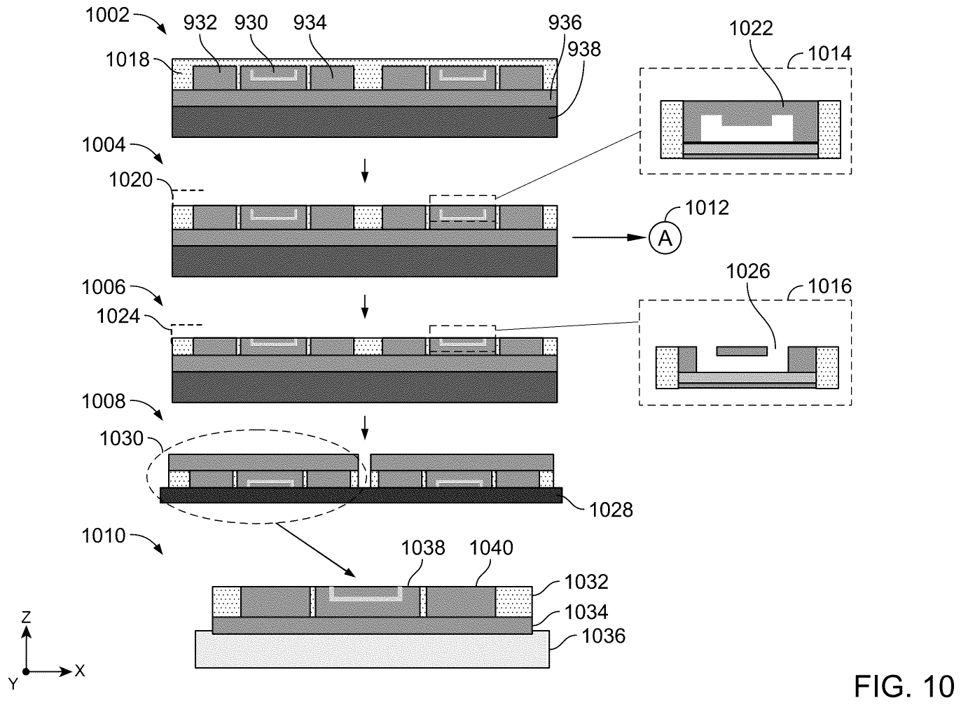

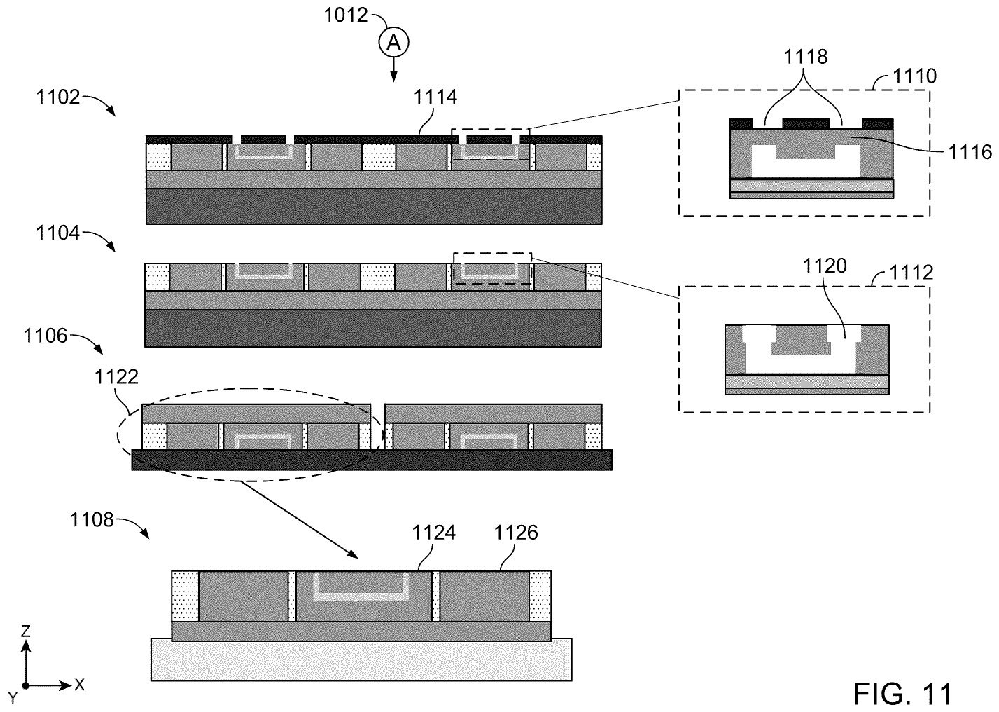

FIG. 8 is a flowchart illustrating an example process 800 for manufacturing a cooling apparatus including opening inlet and outlet portions of an integrated cooling assembly that are closed. FIGS. 9-11 show schematic sectional views of example structures that may correspond to one or more blocks of the process 800. FIG. 9 shows schematic views 902-908 illustrating some example structures having a plurality of integrated cooling assemblies with inlet and outlet portions that are closed at a cold plate backside of each integrated cooling assembly. As described herein, a closed inlet portion or a closed outlet portion refers to a channel including an obstructive material such that materials from outside the integrated cooling assembly (e.g., debris, contaminants, coolant fluid, etc.) cannot enter or exit the channel volume through the channel. FIGS. 10-11 show schematic views 1002-1010, 1102-1108 of some example structures that may arise during opening of the inlet and outlet portions at the cold plate backside. As described herein, an open inlet portion or an open outlet portion refers to a channel through which materials from outside the integrated cooling assembly, such as coolant fluid, may enter or exit the channel volume. Here, the process 800 may be employed in forming a cooling apparatus including an integrated cooling assembly as illustrated at FIGS. 1-7. The process 800 is described in the following paragraphs with reference to the schematic views 1002-1010, 1102-1108 for illustrative purposes and should not be construed as limited to the example structures or parts thereof.

Referring to block 802 of FIG. 8, an integrated cooling assembly is formed. Forming the integrated cooling assembly may include attaching a cold plate to a backside of the first die. In some embodiments, the cold plate is directly bonded to the backside of the first die. The cold plate may be attached to the backside of the first die using direct dielectric bonding or direct hybrid bonding. A first side of the cold plate, or at least a portion thereof, is spaced apart from the backside of the first die to define a channel volume having an inlet portion and an outlet portion that are closed at a second side of the cold plate opposite to the first side. That is, a first portion of the cold plate, such as perimeter sidewalls of the cold plate, may be bonded to the backside of the first die, and a second portion of the cold plate may be spaced apart from the backside of the first die to define the channel volume having the inlet portion and the outlet portion. Here, the inlet and outlet portions are closed at a side of the cold plate facing away from the backside of the first die, such as the cold plate backside 707. The closed inlet portion and/or the closed outlet portion includes an obstructive material such that materials from outside the integrated cooling assembly (e.g., debris, contaminants, coolant fluid, etc.) cannot enter or exit the channel volume through the inlet portion or the outlet portion. The first side of the cold plate may be patterned, such as the portion of the cold plate spaced apart from the backside of the first die. The patterning may include forming cavity dividers extending away from the portion of the cold plate towards the backside of the first die, such as the support features 230.

In some embodiments, a plurality of integrated cooling assemblies is formed by directly bonding a first substrate and a second substrate. That is, the first substrate comprises a plurality of first dies having respective die backsides disposed at a side of the first substrate, and the second substrate comprises a plurality of cold plates having respective first cold plate portions disposed at a side of the second substrate and respective second cold portions. The respective first cold plate portions may correspond to perimeter sidewalls of the cold plate after singulation. The respective second cold portions may correspond to a top cold plate portion after singulation, the top cold plate portion at least partially defining a channel volume between the cold plate and the die backside. Forming the plurality of integrated cooling assemblies may include bonding the side of the second substrate to the side of the first substrate such that the respective first cold plate portions of the plurality of cold plates are bonded to the respective die backsides of the plurality of first dies, the respective second cold plate portion of each cold plate being spaced apart from the backside of the corresponding first die. Here, a frontside of each cold plate faces towards the backside of a corresponding first die and a backside of the cold plate faces away from the backside of the corresponding first die. Forming the integrated cooling assembly may include singulating the plurality of integrated cooling assemblies, each singulated integrated cooling assembly comprising a cold plate having at least a respective cold plate portion attached to a backside of a first die, such as perimeter sidewalls of the cold plate defined by the singulation being attached to the backside of the first die.

Referring to the schematic view 902 at FIG. 9, a first substrate is shown comprising one or more first dies. Here, at least two first dies are shown. The first die includes a dielectric layer 910, a die substrate 912, and an active side 914. The dielectric layer 910 is disposed at a first side of the die substrate 912, and the active side 914 is disposed at a second side of the die substrate 912 opposite to the first side of the die substrate 912. Here, the dielectric layer 910 and/or first side of the die substrate 912 may be part of a die backside of a first die. The dielectric layer 910 may be a protective and/or bonding layer. In some embodiments, the dielectric layer 910 can be an inorganic dielectric layer, such as a layer comprising silicon nitride which acts as the corrosion protective layer or a corrosion resistant barrier layer, preventing undesired corrosion of a semiconductor material which might be in direct contact with a coolant fluid flowing through a coolant chamber volume, such as a material of the die substrate 912 and/or the active side 914.

In some embodiments, the method further includes preparing a first die, such as the first substrate comprising the one or more first dies, for attaching a cold plate. Here, the first die may be prepared for bonding the cold plate. That is, preparing the first substrate for bonding may include forming the dielectric layer 910 on the first side of the die substrate 912. Preparing the first substrate for bonding may include planarizing the dielectric layer 910 and/or the first side of the die substrate 912. The active side 914 includes one or more components, such as semiconductor device elements, circuit elements, compute blocks, etc. Here, the active side 914 may include logic component(s). The dielectric layer 910 may form a die backside of the first die. It is appreciated that the first substrate may include any number and arrangement of first dies.

At the schematic view 904, one or more integrated cooling assemblies are formed by attaching a cold plate to a backside of a first die. Here, a second substrate 916 includes one or more cold plates directly bonded to the respective die backsides of the one or more first dies of the first substrate. Each cold plate is disposed on the dielectric layer 910 of a corresponding first die. A cold plate frontside, or a portion thereof, of each cold plate is spaced apart from the die backside of the corresponding first die to define a channel volume therebetween. In some embodiments, the cold plate frontside, such as the portion spaced apart from the die backside, is patterned. The patterned cold plate portion may include cavity dividers, such as the support features 230. The cold plate frontside faces towards the die backside of the first die. The cold plate includes a cold plate backside opposite to the cold plate frontside. The channel volume includes an inlet portion 918 and an outlet portion 920. In some embodiments, the inlet portion 918 and the outlet portion 920 are closed by respective portions of the cold plate. Here, the inlet portion 918 is closed at a cold plate backside by a cold plate portion, such as a first cold plate portion 922, and the outlet portion 920 is closed at the cold plate backside by another cold plate portion, such as a second cold plate portion 924. That is, the cold plate portions 922, 924 block exterior materials entering the inlet/outlet portions 918, 920 into the channel volume. The first substrate and the second substrate 916 are directly bonded to form the one or more integrated cooling assemblies, each integrated cooling assembly including at least one cold plate and at least one first die. In some embodiments, one or more cold plate portions, such as the first cold plate portion 922, may have a thickness along a direction orthogonal to a backside of a first die in a range from about 10 μm to about 200 μm. The one or more cold plate portions may have a thickness relative to a thickness of the cold plate along the direction orthogonal to the backside of a first die, such as in a range from about 0.1% of the cold plate's thickness to about 70% of the cold plate's thickness. For example, the cold plate may have an overall thickness of about 500 μm, and the first cold plate portion 922 may have a thickness of about 50 μm or about 10% of the cold plate's thickness.

In some embodiments, the one or more integrated cooling assemblies are singulated. As illustrated at the schematic view 906, a plurality of integrated cooling assemblies is formed after singulating the bonded first and second substrates. Here, the bonded first and second substrates are attached to a temporary carrier, such as a singulation tape 926. Each integrated cooling assembly in the bonded first and second substrates may be disposed apart from one or more neighboring integrated cooling assemblies to define a singulation line 928 therebetween. That is, each cold plate may be aligned with a corresponding die such that the singulation line 928 does not cross through the cold plate and the corresponding die. The integrated cooling assemblies are singulated between neighboring integrated cooling assemblies as indicated at the singulation line 928 to form the plurality of integrated cooling assemblies. Referring to block 804 of FIG. 8, each integrated cooling assembly after singulation may be attached to an interposer, e.g., using a pick-and-place process or another suitable mounting process, and/or variants thereof.

At block 804, the integrated cooling assembly is attached to an interposer, wherein a plurality of second dies is disposed on the interposer. In some embodiments, the method further includes directly bonding the plurality of second dies to the interposer, wherein the plurality of second dies is disposed adjacent to the integrated cooling assembly. The plurality of second dies may include two or more second dies disposed adjacent to different sides of the first die. In some embodiments, attaching the integrated cooling assembly to the interposer forms interconnections between the first die and each of the plurality of second dies.

Referring to the schematic view 908 at FIG. 9, a structure includes at least one integrated cooling assembly 930, second dies 932, 934, an interposer 936, and a carrier substrate 938. In some embodiments, one or both of second dies 932, 934 may be stacked dies. A first side of the interposer 936 is disposed on the carrier substrate 938. The at least one integrated cooling assembly 930 and the second dies 932, 934 are disposed on a second side of the interposer 936. The second side of the interposer 936 may be opposite to the first side. The second dies 932, 934 are attached to the interposer 936. In some embodiments, the second dies 932, 934 are bonded to the interposer 936. In some embodiments, the second dies 932, 934 may be micro-bump bonded and/or flip chip bonded to the interposer 936. In some embodiments, the second dies 932, 934 may be hybrid bonded to the interposer 936. The integrated cooling assembly 930 and the second dies 932, 934 may be attached to the interposer 936 in any order. That is, the second dies 932, 934 may be attached to the interposer 936 first, and then the integrated cooling assembly 930 may be attached to the interposer 936. Alternatively, the integrated cooling assembly 930 may be attached to the interposer 936 before attaching the second dies 932, 934 to the interposer 936.

Here, the integrated cooling assembly after singulation at the view 906 is removed from the singulation tape 926 (labeled the integrated cooling assembly 930). An assembly frontside 940 of the integrated cooling assembly 930 is attached to the interposer 936. The active side 914 of the first die may be attached to the second side of the interposer 936 using any suitable process, such as using conductive bumps as described with respect to FIGS. 5 and 7. Here, the active side 914 of the first die of the integrated cooling assembly is bonded to the second side of the interposer 936. An assembly backside of the integrated cooling assembly 930 faces away from the interposer 936. Here, the assembly backside includes the cold plate backside at which the inlet portion 918 and the outlet portion 920 are disposed. It is noted that, at a manufacturing phase corresponding to the view 906, the inlet portion 918 and outlet portion 920 are closed by the respective cold plate portions in the integrated cooling assembly 930. Beneficially, the cold plate portions 922, 924 prevent debris and/or other contaminants from entering the channel volume by keeping the inlet portion 918 and outlet portion 920 closed during the manufacturing process. Opening the inlet portion 918 and the outlet portion 920 is described with respect to FIGS. 10-11.

Here, a frontside of the second dies 932, 934 is bonded to the second side of the interposer 936. Attaching the integrated cooling assembly 930 to the interposer 936 forms interconnections between the first die of the integrated cooling assembly 930 and each of the second dies 932, 934. That is, bonding the active side 914 to the interposer 936 may electrically connect one or more components of the active side 914 to conductive features (e.g., interconnects, pads, wiring, routing layer(s), etc.) disposed in the interposer 936. The conductive features may be connected to components of the second dies 932, 934, communicatively coupling the one or more components of the active side 914 and the components of the second dies 932, 934. Here, the integrated cooling assembly 930 is disposed between the second dies 932, 934 on the interposer 936. The integrated cooling assembly 930 and the second dies 932, 934 may be part of a multi-chip module. At the view 908, the structure includes at least two such modules that can be singulated for device packaging during one or more subsequent steps of manufacturing a cooling apparatus as described with respect to FIGS. 10-11. It is contemplated that any number of integrated cooling assemblies and any number of dies may be bonded to the interposer in any order and/or any layout, such as other multi-device packaging layouts, within the principles of the present disclosure.

Returning to FIG. 8 at block 806, subsequent to attaching the integrated cooling assembly to the interposer, the inlet portion and the outlet portion of the channel volume are opened. Here, the inlet portion and the outlet portion are opened by removing an obstructive material within the inlet portion or the outlet portion such that materials from outside the integrated cooling assembly, such as a coolant fluid, may enter or exit the channel volume through the inlet portion or the outlet portion. After opening, the inlet portion and the outlet portion may be fluidly coupled to one or more coolant channels, such as in the manifold 738 and/or in the package cover 708. In some embodiments, the inlet portion and the outlet portion are closed by respective portions of the cold plate. In embodiments where the inlet portion and the outlet portion are closed by respective portions of the cold plate, opening the inlet portion and the outlet portion may include thinning the second side of the cold plate, such as a cold plate backside, to remove the respective portions of the cold plate. In embodiments where the inlet portion and the outlet portion are closed by respective portions of the cold plate, opening the inlet portion and the outlet portion may include patterning the second side of the cold plate to remove the respective portions of the cold plate. Patterning the cold plate may include forming a resist pattern over the second side of the cold plate, the resist pattern having a pattern corresponding to the inlet portion and the outlet portion and etching the respective portions of the cold plate through the pattern.

In some embodiments, prior to opening the inlet portion and the outlet portion, an encapsulant layer is formed over the cold plate. The encapsulant layer is thinned to reveal the second side of the cold plate. Referring to the schematic view 1002 at FIG. 10, a structure includes an encapsulant layer 1018 formed over the interposer 936. The encapsulant layer 1018 extends upwardly from the second side of the interposer 936. Here, the encapsulant layer 1018 extends upwardly to a level over the integrated cooling assembly 930 and the second dies 932, 934. That is, the encapsulant layer 1018 surrounds the integrated cooling assembly 930 and the second dies 932, 934. The encapsulant layer 1018 includes encapsulant portions disposed between the integrated cooling assembly 930 and each of the second dies 932, 934. The encapsulant layer 1018 may comprise one or more organic materials, such as a polymer, an epoxy, a molding compound, or other protective material. The encapsulant layer 1018 may also comprise inorganic materials like silicon oxide, silicon nitride, etc. In some embodiments, a plurality of encapsulant layers is formed over the cold plate. One or more layers of the plurality of encapsulant layers may include a different material than another layer of the plurality of encapsulant layers. Referring to FIGS. 3 and 7, the encapsulant layer 1018 may correspond to the sealing material layer 222 and/or the encapsulant layer 722. The encapsulant layer 1018 is thinned to reveal the cold plate backside.

As shown at the schematic view 1004, the encapsulant layer 1018 is thinned after a first thinning process 1020. The first thinning process 1020 reveals upper portions of the integrated cooling assembly 930 and the second dies 932, 934. Here, the first thinning process 1020 reveals the backsides of the integrated cooling assembly 930 and the second dies 932, 934. That is, the cold plate backside of the integrated cooling assembly 930 is revealed through the first thinning process 1020. The first thinning process 1020 may include a selective stop after removing a portion of the encapsulant layer 1018 and revealing the backsides of the integrated cooling assembly 930 and the second dies 932, 934. The encapsulant layer 1018 at least partially surrounds the sidewalls of the integrated cooling assembly 930 and the second dies 932, 934. A first inset 1014 shows a magnified view of the integrated cooling assembly 930 and portions of the encapsulant layer 1018 after the first thinning process 1020. Here, after the thinning, a thickness of the encapsulant layer 1018 in a direction orthogonal to the backsides of the integrated cooling assembly 930 and the second dies 932, 934 may be about the same as the respective thicknesses of the integrated cooling assembly 930 and/or the second dies 932, 934 in the same direction.

The inlet portion 918 and the outlet portion 920 are closed by their respective cold plate portions, such as a cold plate portion 1022. That is, the cold plate portion 1022 blocks the inlet/outlet portions such that materials from outside the integrated cooling assembly (e.g., debris, contaminants, coolant fluid, etc.) cannot enter or exit the channel volume through the inlet portion or the outlet portion. A thickness of the cold plate portion 1022 along the Z-direction orthogonal to the backsides of the integrated cooling assembly 930 and the second dies 932, 934 may be about the same as the thickness of each of the cold plate portions 922, 924 in the same direction. That is, the first thinning process 1020 may selectively remove the encapsulant portion disposed over the integrated cooling assembly 930 and/or the second dies 932, 934 without thinning the cold plate backside and/or upper portions of the second dies 932, 934.

In some embodiments, thinning the encapsulant layer 1018 includes thinning the respective cold plate portions without opening the inlet portion 918 and the outlet portion 920. That is, the thickness of the cold plate portion 1022 in the Z-direction may be less than the thickness of each of the cold plate portions 922, 924 in the Z-direction, and the inlet portion 918 and the outlet portion 920 remain closed after the thinning. Opening the inlet portion and the outlet portion of the cold plate illustrated at the view 1004 and the inset 1014 may include patterning the second side of the cold plate to remove the respective portions of the cold plate, continuing to block 1012 as described with respect to FIG. 11.

Opening the inlet portion and the outlet portion of the structure illustrated at the view 1004 may include thinning the second side of the cold plate to remove the respective portions of the cold plate. Continuing with reference to the schematic view 1006 at FIG. 10, the process 800 may further include thinning the encapsulant layer 1018 and the revealed upper portions of the integrated cooling assembly 930 and the second dies 932, 934 using a second thinning process 1024. A second inset 1016 shows a magnified view of the integrated cooling assembly 930 after the second thinning process 1024. Here, after the thinning, the cold plate portion 1022 is removed, and a corresponding inlet or outlet portion of the channel volume is opened, such as an open outlet portion 1026. A portion of the cold plate backside is removed by the second thinning process 1024. That is, a first thickness of the cold plate portion 1022 in the Z-direction orthogonal to the cold plate backside may remain disposed over the outlet portion 1026 after the first thinning process 1020. The second thinning process 1024 removes the portion of the cold plate backside having a thickness in the Z-direction of about the same as the first thickness. The thickness of the second dies 932, 934 in the Z-direction may be about the same as the thickness of the integrated cooling assembly 930 in the Z-direction after the second thinning process 1024. That is, if the second dies 932, 934 started with a different thickness in the Z-direction than the integrated cooling assembly 930 at the view 1002, upper portions of the second dies 932, 934 may be removed after the thinning such that the respective thicknesses in the Z-direction of the second dies 932, 934 and the integrated cooling assembly 930 are about the same as shown at the view 1006.

The first thinning process 1020 and the second thinning process 1024 may be different processes. That is, the first thinning process 1020 may selectively remove part of the encapsulant layer 1018, and the second thinning process 1024 may remove part of the encapsulant layer 1018 together with revealed portions of the integrated cooling assembly 930 and the second dies 932, 934. In some embodiments, the first thinning process 1020 and the second thinning process 1024 are the same thinning process. That is, the structure illustrated at the view 1006 is formed by continuous thinning that removes the cold plate portions, such as the cold plate portion 1022, and opens the inlet portion 918 and the outlet portion 920 of the channel volume.

In some embodiments, the interposer and the encapsulant layer are singulated. As described in earlier paragraphs, the first side of the interposer 936 may be disposed on a carrier substrate 938. Backsides of the integrated cooling assembly 930 and the second dies 932, 934 are exposed. As shown at the schematic view 1008, the integrated cooling assembly 930 and the second dies 932, 934 may be attached to a singulation tape 1028. That is, the thinned backsides of the integrated cooling assembly 930 and the second dies 932, 934 are attached to the singulation tape 1028. The carrier substrate 938 is removed. That is, the carrier substrate 938 may be temporarily bonded to the interposer 936. Removing the carrier substrate 938 may include debonding the carrier substrate 938 and the first side of the interposer 936. The interposer 936 and the encapsulant layer 1018 are singulated to form a device 1030. Here, first and second die groups are disposed on the interposer 936, each die group including an integrated cooling assembly and a plurality of second dies. A portion of the encapsulant layer 1018 is disposed between and separates the first die group and the second die group. The interposer 936 and the encapsulant layer 1018 are singulated between the first die group and the second die group. That is, the device 1030 includes the integrated cooling assembly 930, the second dies 932, 934, and the singulated portions of the interposer 936 and the encapsulant layer 1018 after the singulation.

The interposer may be attached to a package substrate after opening the inlet portion and the outlet portion, such as using conductive bumps or direct bonding. In some embodiments, the interposer is bonded to a package substrate after opening the inlet portion and the outlet portion. The interposer may be flip chip bonded to the package substrate. The interposer may be connected to the package substrate through conductive bumps, such as micro-bumps (not shown). At the schematic view 1010, after the singulation, the device 1030 may be attached to a package substrate 1036. The device 1030 includes a device layer 1032 and an interposer 1034. The device layer 1032 includes an integrated cooling assembly 1038 comprising a cold plate attached to a backside of a first die, a plurality of second dies 1040, and an encapsulant layer disposed on the interposer 1034 and surrounding the sidewalls of the integrated cooling assembly 1038 and the plurality of second dies 1040. The first die is communicatively coupled to each of the plurality of second dies 1040 through interconnections of the interposer 1034.

Here, attaching the device 1030 may include flip chip bonding the interposer 1034 to the package substrate 1036. That is, starting at the view 1008, the first side of the interposer 1034 for the device 1030 is revealed by removing the carrier substrate 938 after attaching the thinned backsides of the integrated cooling assembly 930 and the second dies 932, 934 to the singulation tape 1028. The device layer 1032 is disposed on a second side of the interposer 1034 opposite to the first side of the interposer 1034. The first side of the interposer 1034 may include conductive features (e.g., conductive lines, conductive pads, conductive vias, etc.) for electrically coupling components of the device layer 1032 to the package substrate 1036. The conductive features may be revealed by removing the carrier substrate 938. Here, the first side of the interposer 1034 faces upwardly along the Z-direction. Continuing to the view 1010, the device 1030 may be flipped and positioned over the package substrate 1036 such that the first side of the interposer 1034 faces towards the package substrate 1036 downwardly along the Z-direction. Then, the first side of the interposer 1034 is attached to the package substrate 1036, electrically connecting the conductive features to the package substrate. In some embodiments, the conductive features are metallized before flipping the device 1030. That is, conductive bumps, such as the conductive bumps 219, may be deposited on the conductive features. Attaching the first side of the interposer 1034 to the package substrate 1036 may include electrically connecting the conductive bumps to the package substrate 1036. The conductive bumps may be reflowed to form the connections between interposer 1034 and the package substrate 1036. After flipping and attaching the device 1030 to the package substrate 1036, an underfill layer, such as the underfill layer 221, may be formed between the first side of the interposer 1034 and the package substrate 1036, encapsulating the conductive bumps. The device 1030 attached to the package substrate 1036 may be part of a device package, such as the device package 701. That is, a package cover, such as the package cover 708, may be attached to a periphery of the package substrate 1036, the package cover extending over the device 1030.

In some embodiments, opening the inlet portion and the outlet portion may include patterning the second side of the cold plate to remove the respective portions of the cold plate. Continuing to FIG. 11 from block 1012, a resist pattern 1114 is formed over the cold plate backside of the cold plate as shown at the view 1102. Here, the resist pattern 1114 is disposed on the encapsulant layer 1018 after the thinning process 1020, the assembly backside of the integrated cooling assembly 930, and the backsides of the second dies 932, 934. The resist pattern 1114 includes a pattern corresponding to the inlet portion 918 and the outlet portion 920. An inset 1110 shows a magnified view of the integrated cooling assembly 930 after forming the resist pattern 1114. Here, the resist pattern 1114 includes a pattern that defines gaps 1118 disposed over the inlet portion 918 and the outlet portion 920 being closed by respective cold plate portions at the cold plate backside, such as a cold plate portion 1116. The respective cold plate portions are etched through the pattern at the gaps 1118. That is, inlet portion 918 and outlet portion 920 are opened by patterning the cold plate backside through openings of the resist pattern 1114 shown here as the gaps 1118, removing the respective cold plate portions such as a cold plate portion 1116.

At the schematic view 1104, the resist pattern 1114 is removed. An inset 1112 shows a magnified view of the integrated cooling assembly after patterning the cold plate backside. Here, the cold plate portion 1116 has been removed by the patterning, and the corresponding inlet/outlet portion, such as an open outlet portion 1120, is open at the cold plate backside. The thickness of the integrated cooling assembly 930 in the Z-direction orthogonal to the cold plate backside may be about the same after the patterning as the thickness of the integrated cooling assembly 930 in the Z-direction before the patterning. That is, the patterning removes portions of the cold plate, such as the cold plate portion 1116, that close the inlet/outlet portions. The openings formed by removing the cold plate portions may be smaller, about the same, or larger than the corresponding inlet/outlet portions. That is, the openings after removing the cold plate portions may have about the same lateral dimension (e.g., width, diameter, etc.) or a different lateral dimension than the corresponding inlet/outlet portions. Here, the open outlet portion 1120 includes an upper Z-direction section formed by removing the cold plate portion 1116 and a lower Z-direction section that is part of the channel volume of the integrated cooling assembly 930. A lateral width of the upper Z-direction section in the X-direction (and/or in the Y-direction) orthogonal to a sidewall of the open outlet portion 1120 is greater than a lateral width of the lower Z-direction section in the same direction. In some embodiments, the lateral width of the upper Z-direction section in the X-direction (and/or in the Y-direction) orthogonal to a sidewall of the open outlet portion 1120 is about the same as or less than a lateral width of the lower Z-direction section in the same direction.

As described with respect to the views 1008, 1010, the interposer 936 and the encapsulant layer 1018 may be singulated. As shown at the schematic view 1106, the backsides of the integrated cooling assembly 930 and the second dies 932, 934 are attached to a singulation tape. The carrier substrate 938 is removed. First and second die groups are disposed on the interposer 936, each die group including an integrated cooling assembly and a plurality of second dies. A portion of the encapsulant layer 1018 is disposed between and separates the first die group and the second die group. The interposer 936 and the encapsulant layer 1018 are singulated between the first die group and the second die group to form a device 1122. At the schematic view 1108, the device 1122 is attached to a package substrate. Here, attaching the device 1122 may include flip chip bonding the interposer to the package substrate. That is, the device 1122 may be flipped and positioned over the package substrate, where a first side of the interposer, the first side being opposite to a second side of the interposer on which a device layer is disposed, faces towards and is attached to the package substrate. The device 1122 includes an integrated cooling assembly 1124 comprising a cold plate attached to a backside of a first die, a plurality of second dies 1126, and an encapsulant layer disposed on the interposer. The encapsulant layer surrounds the sidewalls of the integrated cooling assembly 1124 and the plurality of second dies 1126. The first die is communicatively coupled to each of the plurality of second dies 1126 through interconnections of the interposer.

Any of the devices 1030, 1122 may be placed into a device package, such as the device package 701. That is, the package substrate 1036 may correspond to any of the package substrates 202, 502, or 702. In some embodiments, subsequent to bonding the interposer to the package substrate, a manifold, such as the manifold 738, is attached to the integrated cooling assembly 1124, the manifold comprising one or more channels in fluid communication with the channel volume of the integrated cooling assembly 1124. In some embodiments, subsequent to bonding the interposer to the package substrate, one or more heat dissipation devices, such as the heat dissipation devices 734, 735, are attached to at least one second die of the plurality of second dies 1126.

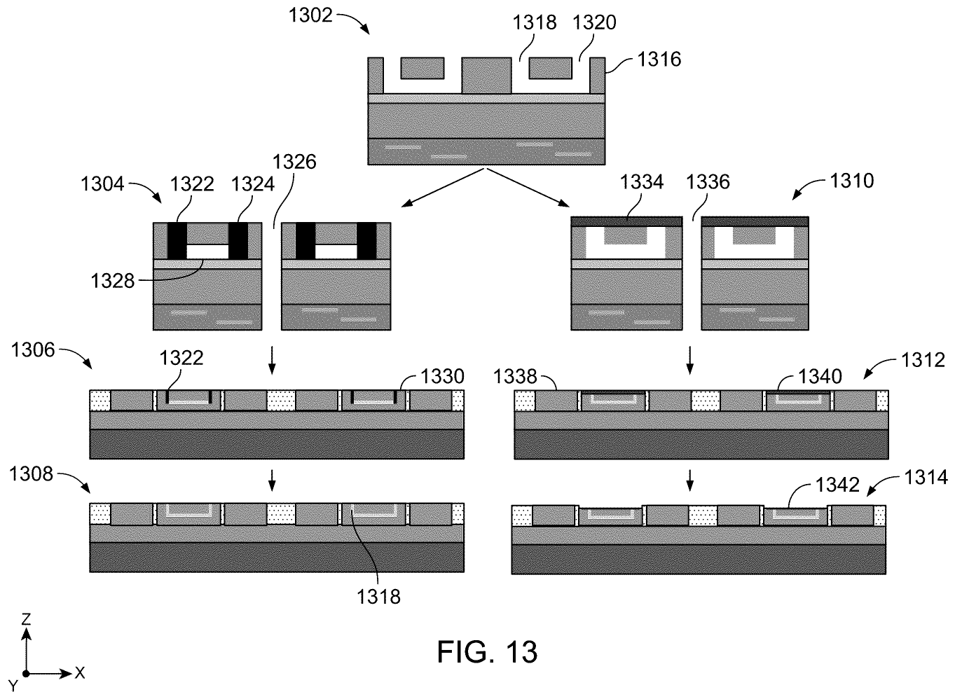

FIG. 12 is a flowchart illustrating an example process 1200 for manufacturing a cooling apparatus including closing the inlet and outlet portions of an integrated cooling assembly. FIG. 13 shows schematic sectional views 1302-1314 of some example structures that may arise during a manufacturing process including closing the inlet and outlet portions of an integrated cooling assembly. These example structures may correspond to one or more blocks of the process 1200. The example structures as illustrated at the schematic views 1302-1314 include a plurality of integrated cooling assemblies with inlet and outlet portions that are open at a first side. Here, the process 1200 may be employed in forming a cooling apparatus including an integrated cooling assembly as illustrated at FIGS. 1-7. The process 1200 is described in the following paragraphs with reference to the views 1302-1314 for illustrative purposes and should not be construed as limited to the example structures or parts thereof.

At block 1202, an integrated cooling assembly is formed, the integrated cooling assembly comprising a cold plate attached to a backside of a first die. The cold plate has an inlet portion and an outlet portion that are open at a side of the cold plate.

Here, at the view 1302, one or more integrated cooling assemblies are formed, each integrated cooling assembly 1316 including a cold plate attached to a backside of a first die. Analogous to the views 902-904, a first substrate comprising a plurality of first dies may be bonded to a second substrate comprising a plurality of cold plates. The integrated cooling assembly 1316 includes a channel volume between a cold plate frontside and a die backside of the first die. Here, the channel volume of the integrated cooling assembly 1316 includes an inlet portion 1318 and an outlet portion 1320 that are open at the cold plate backside. A plurality of integrated cooling assemblies including the integrated cooling assembly 1316 may be singulated at the singulation line 1326 as illustrated at the schematic view 1304 or at the singulation line 1336 between neighboring integrated cooling assemblies as illustrated at the schematic view 1310.

At block 1204, the inlet portion and the outlet portion are closed. That is, an obstructive material is disposed within the inlet portion and the outlet portion such that the material from outside the integrated cooling assembly cannot enter or exit a channel volume of the integrated cooling assembly through the inlet portion or the outlet portion. In some embodiments, closing the inlet portion and the outlet portion includes disposing respective removable plugs within the inlet portion and the outlet portion. In some embodiments, closing the inlet portion and the outlet portion includes forming a removable film over at least a portion of the second side of the cold plate, wherein the inlet portion and the outlet portion are closed by the removable film. At block 1206, the integrated cooling assembly is attached to an interposer, wherein attaching the integrated cooling assembly to the interposer forms interconnections between the first die and each of a plurality of second dies. At block 1208, an encapsulant layer is formed over the interposer. At block 1210, the encapsulant layer is thinned to reveal the inlet portion and the outlet portion. In some embodiments, thinning the encapsulant layer includes revealing the respective removable plugs. In some embodiments, thinning the encapsulant layer includes revealing the removable film. At block 1212, the inlet portion and the outlet portion are opened. Opening the inlet portion and the outlet portion may include removing the respective removable plugs. Opening the inlet portion and the outlet portion may include removing the removable film.

The inlet portion and the outlet portion may be closed by respective removable plugs. As used herein, the term “plug” refers to a piece of obstructive material fitting into an opening to fluidly seal the opening. That is, the removable plugs block material from outside the integrated cooling assembly. The blocked material cannot enter or exit a channel volume of the integrated cooling assembly through the opening in which the plug is disposed. The removable plugs may be disposed within openings of the inlet/outlet portions, extending laterally in the X-Y plane between sidewalls around the inlet/outlet portions to block the material from outside the integrated cooling assembly. The removable plugs may comprise a sacrificial material that can be selectively removed as described with respect to the view 1308. The sacrificial material may be applied using a coating technique, such as spray coating, such that fluid flow of the sacrificial material into one or more fluid channels of an integrated cooling assembly is desirably reduced or minimized. In some embodiments, the removable plugs comprise an organic polymer. The sacrificial material may include a photoresist. That is, some examples of the sacrificial material include a polyimide, a benzocyclobutene (BCB), polytetrafluoroethylene (PTFE) or other fluoropolymer, or other polymer material that may include one or more photosensitive components, such as a photosensitive polyimide, a photosensitive BCB, or another photosensitive polymer. An example removable film may include a polyimide film, such as Kapton™ film with silicon adhesive or another adhesive material. An example removable plug may be formed (e.g., machined) from a PTFE material, such as Teflon™. The plug may be removed after encapsulation and/or thinning as described with respect to the view 1308. The views 1304-1308 show some example structures after closing the inlet portion 1318 and the outlet portion 1320 with respective removable plugs, here an inlet plug 1322 and an outlet plug 1324.

The cold plate may include a removable film disposed over at least a portion of the second side of the cold plate, wherein the inlet portion and the outlet portion are closed by the removable film. That is, the removable film blocks material from outside the integrated cooling assembly. The blocked material cannot enter or exit a channel volume of the integrated cooling assembly through the inlet portion or the outlet portion. The removable film may be partially disposed within openings of the inlet/outlet portions and cold plate portions around the openings of the inlet/outlet portions to block the material from outside the integrated cooling assembly. The views 1310-1314 show some example structures after closing the inlet portion 1318 and the outlet portion 1320 with a removable film, here a film 1334.

Here, plugs 1322, 1324 and/or the film 1334 may comprise a sacrificial material, such as a water-soluble material. The plugs 1322, 1324 and/or the film 1334 may have been formed using a spin-coating process. That is, an amount of sacrificial material corresponding to the plugs or film may be disposed as a liquid on a portion of the cold plate backside and spread through rotation of the structure. For the plugs disposed within the inlet portion and the outlet portion, coating material disposed outside the inlet portion and the outlet portion after the spin-coating process may be removed. It is appreciated that forming the plugs 1322, 1324 and/or the film 1334 is intended to be illustrative and non-limiting. Any suitable techniques for depositing the sacrificial material and closing the inlet portion and the outlet portion may be employed within the principles of the present disclosure.

At the view 1304, the inlet portion 1318 is closed by disposing an inlet plug 1322 therein, and the outlet portion 1320 is closed by disposed an outlet plug 1324 therein. The plugs 1322, 1324 may be disposed through their respective inlet/outlet portions of the channel volume. That is, the inlet plug 1322 and the outlet plug 1324 may extend from the cold plate backside to the die backside 1328. In some embodiments, the plugs 1322, 1324 extend to a level above the die backside, such as from the cold plate backside to about a level of the cold plate frontside. The plugs 1322, 1324 may form a protective seal for their respective inlet/outlet portions. That is, the protective seal formed by the plugs 1322, 1324 close their respective inlet/outlet portions and prevent exterior material entering the channel volume of the integrated cooling assembly through the inlet portion 1318 or the outlet portion 1320. Here, the inlet plug 1322 is disposed within an opening of the inlet portion 1318, extending laterally in the X-Y plane between sidewalls of the inlet portion 1318 to form a seal between the inlet plug 1322 and the sidewalls of the inlet portion 1318. The outlet plug 1324 is disposed within an opening of the outlet portion 1320, extending laterally in the X-Y plane between sidewalls of the inlet portion 1320 to form a seal between the outlet plug 1324 and the sidewalls of the outlet portion 1320. By sealing the respective openings of the inlet/outlet portions 1318, 1320, the plugs 1322, 1324 prevent exterior material from entering the channel volume of the integrated cooling assembly. Beneficially, the plugs 1322, 1324 prevent debris and/or contaminants from entering the channel volume of the integrated cooling assembly 1316.

Analogous to the views 1002-1004, the integrated cooling assembly 1316 is attached to an interposer between at least two second dies as shown at the view 1306. Here, the plugs 1322, 1324 keep the inlet/outlet portions 1318, 1320 closed at the cold plate backside, such as a cold plate backside 1330. An encapsulant layer is formed over the interposer. The encapsulant layer is thinned to reveal the inlet/outlet portions at the cold plate backside 1330, e.g., using the first thinning process 1020. Here, thinning the encapsulant layer reveals the plugs 1322, 1324. At the view 1308, the inlet portion 1318 and the outlet portion 1320 are opened by removing the plugs 1322, 1324. Here, the plugs 1322, 1324 may be selectively removed using a solvent. That is, the plugs 1322, 1324 may be water-soluble or removable using another solution, and the plugs 1322, 1324 are removed using the corresponding solution. The channel volume is open at the cold plate backside after removing the plugs 1322, 1324, such as at the inlet portion 1318 after removing the inlet plug 1322. In some embodiments, removing the respective removable plugs includes cleaning the channel volume. In some embodiments, the plugs 1322, 1324 comprise an oxide, and removing the plugs 1322, 1324 includes dry etching the oxide. Analogous to the views 1008-1010, the interposer and encapsulant layer may be singulated to form a device, such as the device 1030, that can be included in a device package. It is noted that the integrated cooling assembly and the second dies may not be thinned by removing the plugs 1322, 1324.

At the view 1310, the inlet portion 1318 and the outlet portion 1320 are closed by disposing the film 1334 over the assembly backside of the integrated cooling assembly 1316. The film 1334 may be disposed over a plurality of integrated cooling assemblies. The film 1334 may form a protective seal to close the inlet/outlet portions. That is, the protective seal formed by the film 1334 closes the inlet/outlet portions 1318, 1320 and prevents exterior material from entering the channel volume of the integrated cooling assembly through the inlet portion 1318 or the outlet portion 1320. Here, the film 1334 is disposed on at least portions of the backside of the integrated cooling assembly 1316 around the inlet portion 1318 and the outlet portion 1320, extending over respective openings of the inlet portion 1318 and the outlet portion 1320. The film 1334 is adhered to the portions of the backside of the integrated cooling assembly 1316 to form a seal around the respective openings of the inlet portion 1318 and the outlet portion 1320. By sealing the respective openings of the inlet/outlet portions 1318, 1320, the film 1334 prevents exterior material from entering the channel volume of the integrated cooling assembly. The film 1334 may be singulated with the integrated cooling assembly 1316. That is, the film 1334 may be disposed on the backsides of the plurality of integrated cooling assemblies prior to singulating the integrated cooling assembly 1316. After singulation, a portion of the film 1334, such as a singulated film 1340, remains on each integrated cooling assembly. Here, the singulated film 1340 is disposed over the inlet portion 1318 and the outlet portion 1320.

Analogous to the views 1002-1004, the integrated cooling assembly 1316 is bonded to an interposer between at least two second dies as shown at the view 1312. Here, the singulated film 1340 keeps the inlet/outlet portions 1318, 1320 closed at the cold plate backside. That is, the singulated film 1340 maintains a seal around the respective openings of the inlet portion 1318 and the outlet portion 1320. An encapsulant layer is formed over the interposer. The encapsulant layer is thinned to reveal the inlet/outlet portions at the cold plate backside, e.g., using the first thinning process 1020. Here, thinning the encapsulant layer reveals the singulated film 1340 and the backsides 1338 of the second dies. A thickness of the integrated cooling assembly 1316 along the Z-direction orthogonal to the cold plate backside may be different than a thickness of the second dies in the Z-direction after thinning the encapsulant layer. That is, the integrated cooling assembly and the singulated film 1340 may have a same total thickness in the Z-direction as the second dies in the same direction.

At the view 1314, the inlet portion 1318 and the outlet portion 1320 are opened by removing the singulated film 1340. In some embodiments, the singulated film 1340 comprises a sacrificial material, such as a soluble material, and is removed using the corresponding removal process, such as a corresponding solvent. In some embodiments, the singulated film 1340 is stripped away using a stripping process, such as organic stripping or dry stripping. After removing the singulated film 1340, the channel volume is open at a cold plate backside 1342. Here, the cold plate backside 1342 is disposed at a different level than the backsides of the second dies since the thickness of the integrated cooling assembly 1316 in the Z-direction is different than the respective thicknesses of the second dies in the same direction. The difference in thickness in the Z-direction may remain after singulating the interposer and encapsulant layer to form a device as described with respect to the views 1008-1010.

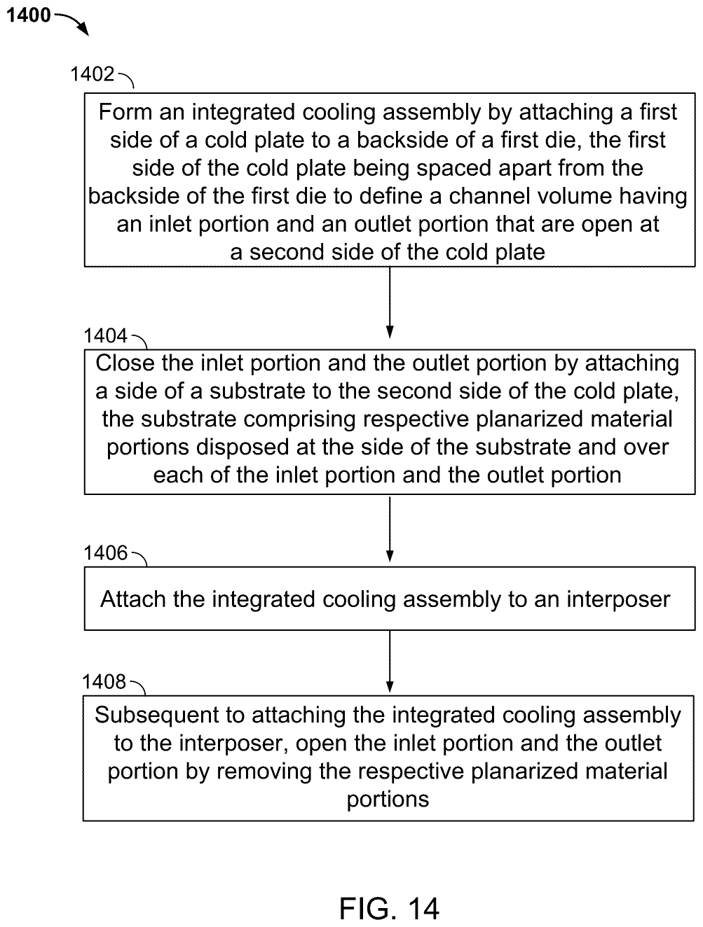

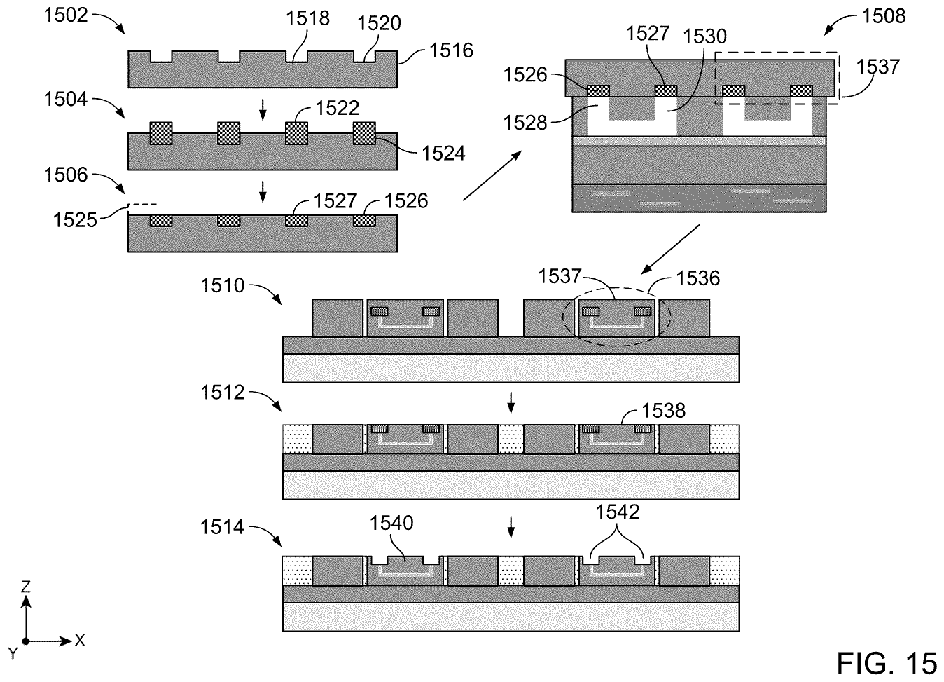

FIG. 14 is a flowchart illustrating an example process 1400 for manufacturing a cooling apparatus including bonding a substrate that closes the inlet and outlet portions of an integrated cooling assembly. FIG. 15 shows schematic sectional views 1502-1514 of some example structures that may arise during manufacturing of a cooling apparatus including bonding a substrate that closes the inlet and outlet portions of an integrated cooling assembly. These example structures may correspond to one or more blocks of the process 1400. The example structures as illustrated at the views 1502-1514 include a plurality of integrated cooling assemblies with inlet and outlet portions that are open at a first side. Here, the process 1400 may be employed in forming a cooling apparatus including an integrated cooling assembly as illustrated at FIGS. 1-7. The process 1400 is described in the following paragraphs with reference to the views 1502-1514 for illustrative purposes and should not be construed as limited to the example structures or parts thereof.

At block 1402, an integrated cooling assembly is formed. The integrated cooling assembly includes a cold plate having at least a first cold plate portion attached to a backside of a first die. A second portion of the cold plate is spaced apart from the backside of the first die to define a channel volume having an inlet portion and an outlet portion that are open at a side of the cold plate, here a cold plate backside, that faces away from the backside of the first die. An integrated cooling assembly may be formed as described with respect to the view 1302. The integrated cooling assembly includes an inlet portion 1528 and an outlet portion 1530 that are open at the cold plate backside as shown at the view 1508.

At block 1404, the inlet portion and the outlet portion are closed by attaching a side of a substrate to the cold plate backside of the cold plate. The substrate comprises respective planarized material portions disposed at the side of the substrate and over each of the inlet portion and the outlet portion. In some embodiments, a substrate is prepared, the substrate having cavities disposed at the side of the substrate, wherein a first cavity of the cavities corresponds to the inlet portion and a second cavity of the cavities corresponds to the outlet portion. Preparing the substrate may include forming a planarizable material in the cavities and forming the respective planarized material portions by planarizing the side of the substrate and the planarizable material. That is, a sacrificial material may be formed in the cavities that is amenable to planarizing and/or polishing processes, such as silicon oxide.

Returning to the view 1502, a substrate 1516 is prepared. Here, the substrate 1516 includes a first cavity 1520 corresponding to the inlet portion 1528 and a second cavity 1518 corresponding to the outlet portion 1530. That is, referring to the view 1508, the first cavity 1520 may be positioned at a site that would be disposed over the inlet portion 1528, and the second cavity 1518 may be positioned at a site that would be disposed over the outlet portion 1530 after bonding the substrate 1516 to the integrated cooling assembly. The cavities 1520, 1518 are disposed at a first side of the substrate 1516. Here, the first side of the substrate 1516 would face towards the cold plate backside of the cold plate when attached as shown at the view 1508.

At the view 1504, a first material portion 1524 is disposed at the first cavity 1520, and a second material portion 1522 is disposed at the second cavity 1518. Here, the material portions 1524, 1522 overfill their respective cavities 1520, 1518, extending vertically along the Z-direction to a level over the substrate 1516 for planarizing the material portions 1524, 1522. The material portions 1524, 1522 may comprise a planarizable organic or inorganic material, such as an inorganic dielectric material. In some embodiments, the material portions 1524, 1522 comprise an oxide.

At the view 1506, the first side of the substrate 1516 and the material portions 1524, 1522 are planarized. Here, the first side of the substrate 1516 and the material portions 1524, 1522 may be thinned using a thinning process 1525. Planarized material portions 1527, 1526 remain after using the thinning process 1525 on the material portions 1524, 1522. That is, the first side of the substrate 1516 and the material portions 1524, 1522 may be planarized using chemical-mechanical polishing (CMP), collectively forming a bondable interface. After thinning, the planarized material portions 1527, 1526 extend from a base of a cavity within the substrate along the Z-direction to about a same level as the first side of the substrate 1516 along the Z-direction. The planarized material portions 1527, 1526 may fill the cavity, extending laterally in the X-Y plane between sidewalls around the cavity.

At the view 1508, the substrate 1516 is attached to the cold plate backside of the integrated cooling assembly. Here, the first side of the substrate 1516 is directly bonded to the cold plate backside. The planarized material portion 1526 is disposed over the inlet portion 1528, and the planarized material portion 1527 is disposed over the outlet portion 1530. Attaching the first side of the substrate 1516 to the integrated cooling assembly closes the inlet portion 1528 using the planarized material portion 1526 and the outlet portion 1530 using the planarized material portion 1527. That is, bonds may be formed between the first side of the substrate 1516 and the cold plate backside such that the first side of the substrate 1516 and/or the planarized material portions 1526, 1527 are substantially flush with at least portions of the cold plate backside of the integrated cooling assembly around respective openings of the inlet/outlet portions 1528, 1530. Here, a lateral area of the planarized material portions 1526, 1527 along a direction parallel to the cold plate backside in the X-Y plane may be about the same as a lateral area of the corresponding inlet/outlet portions 1530, 1528 in the same direction It is contemplated that one or more planarized material portions may have a lateral area along a direction parallel to the cold plate backside in the X-Y plane that is different from a lateral area of corresponding inlet/outlet portions in the same direction. That is, a lateral area of a planarized material portion may be greater than a lateral area of an inlet or outlet portion.

The bonds may form a seal around the respective openings of the inlet portion 1318 and the outlet portion 1320. By forming the seal around the respective openings of the inlet/outlet portions 1318, 1320, the substrate 1516 bonded to the cold plate backside of the integrated cooling assembly prevents exterior material from entering the channel volume of the integrated cooling assembly, closing the inlet portion 1318 and the outlet portion 1320. Analogous to the views 1310-1312, the integrated cooling assembly and the bonded first substrate may be singulated to form a bonded structure 1536. The bonded structure 1536 includes a singulated substrate portion 1537, where the first side of the singulated substrate portion 1537 is bonded to the cold plate backside of the integrated cooling assembly. After singulating, the first die of the integrated cooling assembly may be bonded to an interposer as shown at the view 1510.

At block 1406, the integrated cooling assembly is attached to an interposer. At the view 1510, the bonded structure 1536 is bonded to a side of the interposer. Here, a plurality of second dies is attached to the interposer. The first die is communicatively coupled to the plurality of second dies through interconnections of the interposer. At the view 1512, an encapsulant layer is formed over the interposer. The encapsulant layer is thinned to reveal a second side 1538 of the singulated substrate portion 1537. Backsides of the second dies may be thinned to about the same level as the second side 1538. Here, the second side 1538 is opposite to the first side of the singulated substrate portion 1537 that is bonded to the cold plate backside. Thinning the encapsulant layer may include revealing the planarized material portions 1526, 1527 at the second side 1538. Here, the singulated substrate portion 1537 remains bonded to the integrated cooling assembly. After thinning the encapsulant layer and singulated substrate portion 1537, a thickness of the bonded structure 1536 along the Z-direction orthogonal to the cold plate backside may be about the same as the respective thicknesses of the second dies along the Z-direction. Here, the integrated cooling assembly has a thickness in the Z-direction that is less than the thickness of the second dies in the same direction.

At block 1408, the inlet portion and the outlet portion are opened subsequent to attaching the integrated cooling assembly to the interposer by removing the respective planarized material portions. At the view 1514, the inlet portion 1528 and the outlet portion 1530 are opened. Here, the planarized material portions 1526, 1527 are removed, leaving a structural material layer 1540 having a pattern that defines gaps 1542 disposed through the structural material layer 1540. In some embodiments, removing the planarized material portions 1526, 1527 includes etching the planarized material portions 1526, 1527. That is, the planarized material portions 1526, 1527 may comprise an oxide and are removed using dry etching of the oxide. That is, the gaps 1542 defined by the pattern of the structural material layer 1540 extend from the second side 1538 to the first side of the structural material layer 1540, the first side of the structural material layer 1540 being bonded to the cold plate backside. The inlet portion 1528 and the outlet portion 1530 are open through the gaps 1542 defined by the pattern of the structural material layer 1540. Here, the structural material layer 1540 remains bonded to the backside of the integrated cooling assembly. Analogous to the views 1008-1010, the interposer and encapsulant layer may be singulated to form a device, such as the device 1030, that can be included in a device package. Here, the device may include the structural material layer 1540 bonded to the cold plate backside.

The embodiments discussed above are intended to be illustrative and not limiting. One skilled in the art would appreciate that individual aspects of the cooling assemblies, device packages, and methods discussed herein may be omitted, modified, combined, and/or rearranged without departing from the scope of the disclosure.

1. A method for manufacturing a cooling apparatus, the method comprising:
forming an integrated cooling assembly comprising a cold plate and a first die, the cold plate having first and second portions, by directly bonding the first portion of the cold plate to a backside of the first die, wherein the second portion of the cold plate is spaced apart from the backside of the first die to define a channel volume having an inlet portion and an outlet portion that are closed at a cold plate backside of the cold plate facing away from the backside of the first die;
attaching the integrated cooling assembly to an interposer, wherein a plurality of second dies is disposed on the interposer; and
subsequent to attaching the integrated cooling assembly to the interposer, opening the inlet portion and the outlet portion of the channel volume.

2. The method of claim 1, further comprising directly bonding the plurality of second dies to the interposer, wherein the plurality of second dies is disposed adjacent to the integrated cooling assembly.

3-4. (canceled)

5. The method of claim 1, wherein the inlet portion and the outlet portion are closed by respective portions of the cold plate.

6. The method of claim 5, wherein opening the inlet portion and the outlet portion comprises thinning the cold plate backside to remove the respective portions of the cold plate.

7. The method of claim 5, wherein opening the inlet portion and the outlet portion comprises patterning the cold plate backside to remove the respective portions of the cold plate.

8. (canceled)

9. The method of claim 1, wherein the inlet portion and the outlet portion are closed by respective removable plugs, and wherein opening the inlet portion and the outlet portion comprises removing the respective removable plugs.

10. (canceled)

11. The method of claim 1, wherein the cold plate comprises a removable film disposed over at least a portion of the cold plate backside, wherein the inlet portion and the outlet portion are closed by the removable film, and wherein opening the inlet portion and the outlet portion comprises removing the removable film.

12. The method of claim 1, further comprising, prior to opening the inlet portion and the outlet portion:
forming an encapsulant layer over the cold plate;
thinning the encapsulant layer to reveal the cold plate backside; and
singulating the interposer and the encapsulant layer.

13-16. (canceled)

17. The method of claim 1, wherein the cold plate is attached to the backside of the first die using direct dielectric bonds.

18. The method of claim 1, wherein the cold plate is attached to the backside of the first die using direct hybrid bonds.

19. The method of claim 1, wherein the cold plate comprises:
a perimeter sidewall comprising the first portion of the cold plate;
a top portion comprising the second portion of the cold plate; and
a cavity divider comprising cavity sidewalls, wherein:
the perimeter sidewall extends downwardly from the top portion to the backside of the first die to define a perimeter of the cold plate;
the cavity divider extends downwardly from the top portion towards the backside of the first die; and
the cavity sidewalls, the perimeter sidewall, and the backside of the first die collectively define the channel volume therebetween.

20. A cooling apparatus comprising:
an interposer;
an integrated cooling assembly comprising a cold plate and a first die, the cold plate having a first portion, the first portion being directly bonded to a backside of the first die, wherein the integrated cooling assembly is attached to the interposer; and
a second die communicatively coupled to the first die through the interposer, wherein a thickness of the integrated cooling assembly in a direction orthogonal to the backside of the first die is less than a thickness of the second die in the same direction.

21. The cooling apparatus of claim 20, further comprising a die stack, the die stack having an overall thickness in the same direction, and wherein the thickness of the integrated cooling assembly is less than the overall thickness of the die stack.

22-25. (canceled)

26. The cooling apparatus of claim 20, further comprising an encapsulant layer disposed over the interposer, wherein the interposer and the encapsulant layer are singulated, and wherein the encapsulant layer is planarized such that a thickness of the encapsulant layer in the direction orthogonal to the backside of the first die is about the same as the thickness of the second die in the same direction.

27-28. (canceled)

29. The cooling apparatus of claim 20, wherein the cold plate comprises a second portion and a cold plate backside facing away from the backside of the first die, the second portion being spaced apart from the backside of the first die to define a channel volume having an inlet portion and an outlet portion that are open at the cold plate backside, the cooling apparatus further comprising a structural material layer bonded to the cold plate backside, the structural material layer having a pattern corresponding to the inlet portion and the outlet portion.

30. The cooling apparatus of claim 29, wherein a total thickness of the structural material layer and the integrated cooling assembly in the direction orthogonal to the backside of the first die is about the same as the thickness of the second die in the same direction.

31. The cooling apparatus of claim 20, wherein the first portion of the cold plate is directly bonded to the backside of the first die by direct dielectric bonds.

32. The cooling apparatus of claim 20, wherein the first portion of the cold plate is directly bonded to the backside of the first die by direct hybrid bonds.

33-34. (canceled)

35. The cooling apparatus of claim 20, wherein the cold plate comprises:
a perimeter sidewall comprising the first portion of the cold plate;
a top portion; and
a cavity divider comprising cavity sidewalls, wherein:
the perimeter sidewall extends downwardly from the top portion to the backside of the first die to define a perimeter of the cold plate;
the cavity divider extends downwardly from the top portion towards the backside of the first die; and
the cavity sidewalls, the perimeter sidewall, and the backside of the first die collectively define a channel volume therebetween.

36-43. (canceled)

44. The method of claim 19, wherein the channel volume comprises a plurality of coolant channels defined between the cavity sidewalls, the perimeter sidewall, and the backside of the first die.

45. The cooling apparatus of claim 35, wherein the channel volume comprises a plurality of coolant channels defined between the cavity sidewalls, the perimeter sidewall, and the backside of the first die.
